(19) United States
(12) Patent Application Publication
(10) Pub. No.: US 2009/0134388 A1
(43) Pub. Date: May 28, 2009

(54) SEMICONDUCTOR DEVICE AND FABRICATION METHOD OF SAME

(75) Inventors: Takashi YAMAUCHI, Kanagawa (JP); Yoshifumi Nishi, Kanagawa (JP); Yoshinori Tsuchiya, Kanagawa (JP); Junji Koga, Kanagawa (JP); Koichi Kato, Kanagawa (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/203,409

(22) Filed: Sep. 3, 2008

(30) Foreign Application Priority Data
Nov. 26, 2007 (JP) 2007-304572

(51) Int. Cl. H01L 29/08; H01L 21/06

(52) U.S. Cl. 257/42; 438/102; 257/E21.068; 257/E29.029

(57) ABSTRACT

A semiconductor device having a metal insulator semiconductor field effect transistor (MISFET) with interface resistance-reduced source/drain electrodes is disclosed. This device includes a p-type MISFET formed on a semiconductor substrate. The p-MISFET has a channel region in the substrate, a gate insulating film on the channel region, a gate electrode on the gate insulating film, and a pair of laterally spaced-apart source and drain electrodes on both sides of the channel region. These source/drain electrodes are each formed of a nickel (Ni)-containing silicide layer. The p-MISFET further includes an interface layer which is formed on the substrate side of an interface between the substrate and each source/drain electrode. This interface layer contains magnesium (Mg), calcium (Ca) or barium (Ba) therein. A fabrication method of the semiconductor device is also disclosed.

### CROSS-REFERENCE TO RELATED APPLICATION

This application is based upon and claims priority to Japanese Patent Application No. 2007-304572, filed Nov. 26, 2007, the entire contents of which are incorporated herein by reference.

### FIELD OF THE INVENTION

The present invention relates to a semiconductor device having metal insulator semiconductor (MIS) transistors with interface resistance-reduced source and drain electrodes. This invention also relates to a method of fabricating the semiconductor device.

### BACKGROUND OF THE INVENTION

Silicon ultralarge-scale integration (ULSI) technology is one of key technologies which support infrastructures of highly advanced information societies in future. To enhance the performance of a silicon ULSI chip, it is inevitable to improve performances of metal insulator semiconductor field effect transistors (MISFETs), which are major components of ULSI circuitry. Traditionally, the quest for higher performances of LSI circuit devices has basically relied upon proportional shrinkage of device-feature lengths, also known as “scaling” rules. However, in recent years, it is becoming more difficult, due to various kinds of physical limits, not only to achieve higher performances of on-chip transistors by further miniaturization but also to retain proper operations of such transistor per se.

The physical limits pose problems, one of which is the presence of parasitic resistance of source and drain regions of a transistor. One typical prior known MISFET structure is shown in FIG. 37. As shown herein, this MISFET has its source electrode and drain electrode, at each of which is formed a silicide layer 510. A Schottky junction is formed between this silicide layer 510 and a heavily impurity-doped diffusion layer 508, which is formed around the silicide layer 510, and its associated extension diffusion layer 505. As shown in FIG. 37, the parasitic resistance of the source/drain electrode consists essentially of three resistance components: electrical resistance Rs of the silicide layer per se, resistance Rd of the high-concentration impurity layer, which is inherent to a bulk film, and interface resistance Rc of the above-noted junction.

As is well known, the interface resistance Rc is the greatest one among these three resistance components. This interface resistance does not become smaller in value in accordance with the scaling rules. Accordingly, in order to improve the performance of a future MISFET, it becomes a very important technical issue to reduce or minimize the interface resistance. Regarding the reduction of interface resistance Rc, it has been known that it is important to increase the concentration of an impurity at an interface part between the silicide layer 510 and high-concentration impurity layer 508. For this impurity concentration increase, it is desirable to segregate an activated impurity with higher concentration into a narrower region from the interface—for example, within a range of 20 nanometers (nm). The impurity concentration required here is 5×10¹⁹ atoms per cubic centimeter (cm⁻³) or greater, for example.

See FIG. 38, which is an energy band diagram of Schottky junction to be formed between a silicide layer and its associated silicon (Si) layer with an impurity being heavily doped thereinto to a high level of concentration. An electron behaves to tunnel the mountain of an energy that is equivalent to the Schottky barrier height (SBH) to thereby move or “migrate” between the silicide layer and the high-concentration impurity layer. The tunneling ability of this electron is generally called the tunnel probability among skilled persons in the semiconductor device art. The higher the tunnel probability of junction interface, the lower the electrical interface resistance. It is also known that the tunnel probability exponentially decreases with respect to a product of SBH and tunnel distance. Therefore, effectively reducing the SBH and tunnel distance values leads to a decrease in interface resistance.

FIG. 39 is a graph showing a difference in curvature of Si layer's band due to a difference in impurity concentration of Si layer. As shown FIG. 39, by segregation of an impurity while letting its concentration at the interface between a silicide layer and high-concentration impurity layer be set at a higher level, the effect that makes the band curvature of Si layer stronger takes place, resulting in a decrease in tunnel distance. Furthermore, the SBH per se is reduced as apparent from the energy band diagram of FIG. 39, which was calculated by taking into consideration a image charge effect also. Accordingly, the product of SBH and tunnel distance decreases in value so that the interface resistance Rc is reduced.

As for the silicide film resistance Rs, a recent trend is to employ a nickel silicide (NiSi) film, which is less in electrical resistance than the traditionally used titanium silicide (TiSi₂) and cobalt silicide (CoSi₂) films. The NiSi film of relatively low resistance may be a promising film owing to its several advantages which follow: this film is formable at low temperatures; a shallow silicide layer is fabricatable with a minimal amount of Si consumed; and, the film is adaptable for use in both n-type and p-type MISFETs since the work function is in vicinity of the mid band gap of Si. A typical process flow in the case of this NiSi film being used for silicide layers is shown in FIG. 40.

In view of the fact that NiSi is expected to be the promising material for use as silicide material, it becomes one of the most important issues in terms of the reduction of the interface resistance Rc to lower or minimize the electrical resistance of an interface between NiSi layer and Si layer.

One known approach to lowering the NiSi/Si-layer interface resistance Rc is to force an impurity layer, which was formed by ion implantation prior to the silicide formation, to segregate to the interface of Si and silicide layers during formation of the silicide to thereby form an impurity segregated layer with a higher level of concentration. This is called the impurity segregation process. An example of this process is disclosed in U.S. Pat. No. 7,119,402 to Kinoshita et al., titled “Field Effect Transistor and Manufacturing Method thereof” and assigned to TOSHIBA Corporation.

FIGS. 41A and 41B are graphs showing back-side secondary ion mass spectrometry (SIMS) observation results of an interface between NiSi and Si layers, which was formed by the above-noted impurity pre-doping process. FIG. 41A is in the case of an impurity of the n-type conductivity being used whereas FIG. 42 is in the case of an impurity of the p-type conductivity being used. A typical example of the n-type impurity is arsenic (As). An example of the p-type impurity is boron (B). As shown in FIG. 41A, in the case of the As impurity, the impurity doped is distributed on both sides of the interface. On the contrary, as shown in FIG. 41B, in the case of the B impurity, B atoms doped are trapped by the NiSi film in the process of silicidation whereby many of them are distributed within the NiSi film so that the impurity concentration on Si film side is kept very low.

As apparent from the SIMS observation results, it is suggested that the impurity pre-dope process is not always useful for achievement of high performances of p-type MISFETs although this process is effective in enhancing performances of n-type MISFETs. Accordingly, it can be hardly said that the above-noted process is successfully employable for the purpose of achieving higher performances of a semiconductor device of the type having the complementary metal insulator semiconductor (CMIS) transistor structure with both n-type and p-type MISFETs being formed together on a substrate.

Thus, in order to improve the characteristics of CMIS structure semiconductor devices, it is desired to provide an advanced technique for reducing the interface resistance Rc of n-MISFET while at the same time lowering the interface resistance of p-MISFET. The inventors of the invention as disclosed and claimed herein have already reported that a preferable approach to reducing the interface resistance Rc of pMISFET is to perform ion implantation of the B impurity after having formed the NiSi layer—in other words, employing the so-called impurity post-doping process. For details, see T. Yamaguchi et al., “1 nm NiSi/Si Junction Design based on First-Principles Calculation for Ultimately Low Contact Resistance,” International Electron Devices Meeting (IEDM) Technical Digest, p. 385 (2006).

FIG. 42 is a diagram showing a flow of the impurity post-doping process. SIMS observation results of B atom distribution curves at NiSi/Si Schottky junction interface formed by this impurity post-dope process are graphically shown in FIG. 43. Plots of B impurity concentration observed by SIMS method versus rapid thermal anneal (RTA) temperature are shown in a graph of FIG. 44. As apparent from this graph, an increase in RTA temperature results in an increase in B atom interface concentration. At 500° C., the B interface concentration rises up by one order of magnitude or more when compared to the case of the interface being formed by the impurity pre-dope process.

This has been theoretically explained by the inventors. An attempt was made to calculate a possible change in energy of such interface structure in accordance with impurity atom substitution positions when Si atoms are substituted by B atoms in the NiSi-layer/Si-layer interface structure. A result of this calculation is shown in FIG. 45. A crystal structure diagram is shown at upper part of FIG. 45. At lower part of FIG. 45, a graph is shown, which plots total energy values of resultant crystal structures corresponding to respective cases where circled Si atoms are replaced with B atoms in the crystal structure depicted at upper part of FIG. 45. It can be said that a crystal structure low in energy is more stable than others. It is noted here that the reference of the energy is set to an energy in the case of one Si atom of a bulk Si layer being replaced by an impurity atom—that is, in the case of the plot at the right-side edge of the graph. As apparent from FIG. 45, the energy becomes the lowest when Si atom near the interface is replaced, and a site which becomes energetically the most stable is present in close proximity to the interface. This suggests that B atom has the possibility of segregation to the NiSi-layer/Si-layer interface.

FIG. 46 is a diagram for explanation of the behavior of a B atom for segregation to the NiSi/Si interface in the B impurity post-dope process. The B atom that was ion-implanted into NiSi layer first behaves to enter to an interstitial position between crystal lattices of NiSi—say, the interlattice position. In case B atom resides at the interlattice position as shown in FIG. 46, an energy of the system is higher by about 1 eV than that in the case of B atom being at Si substitution position. For this reason, a few of B atoms may behave to enter to the substitution position of NiSi layer. However, many of the B atoms that were introduced by ion implantation into portions between majority lattices are expected to enter to a substitution position(s) near the interface, which is more stable than the NiSi layer's substitution position, due to the anneal-caused diffusion.

In this way, B atom's segregation to NiSi/Si interface takes place. This kind of segregation rarely occurs in the case of the impurity pre-doping process. This may be explained in a way which follows. The B atom that was doped into a substitution position within Si before silicidation behaves to temporarily enter to the interlattice position. At this time, the energetic stability of B atom at the time it enters to the interlattice position of NiSi layer is much greater than the stability when this B atom exists at the interlattice position of Si. So, B atom is absorbed to the NiSi layer side. Thereafter, the B atom resides at a stable substitution position within bulk NiSi layer before it attempts to return by diffusion to the Si layer side. In addition, it is apparent from FIG. 45 that regarding the substitution position also, the stability of B atom when residing within the bulk NiSi layer is more stable than when residing in a bulk Si. This also contributes to the inhibition of migration of B atom toward the interface side.

FIG. 47 is a graph showing SBH calculation results. Its lateral axis indicates the energy of an electron whereas the longitudinal axis indicates the local density of states (LDOS). For comparison purposes, calculation values in the case of an impurity segregation layer being absent are also shown in this graph. As apparent from FIG. 47, in case a B atom entered to Case 2, SBH is lowered by 0.3 eV. This is ascertainable by measurement of the current-voltage characteristics of a NiSi/Si Schottky junction, which was formed for calculation of the values shown in FIG. 47.

FIG. 48 is a graph showing a relation of SBH modulation width versus B impurity concentration. The vertical axis of this graph indicates a measured value of the SBH modulation width; the lateral axis is the concentration of B atom at an interface. The SBH modulation width is almost proportional to the interface concentration. It can be seen that in the case of the impurity post-doping process using a 500° C. anneal, modulation of more than 0.2 eV (70% of calculated value) is obtainable. At this time, as shown by SIMS experimentation result of FIG. 43, many B atoms are residing within NiSi layer; thus, it can be considered that this SBH modulation effect is distinctly different from the SBH reduction occurring due to either the band curvature effect or the image charge effect shown in FIG. 39.

FIG. 49 is a diagram for explanation of SBH modulation by means of dipoles. As shown in a partial enlarged crystal structure diagram at left part of FIG. 49, it is considered that SBH is modulated by a dipole (electrical duplex) which is generated near or around a B atom that was entered to a nearby position of the interface. Based on this principle, the inventors as named herein have proposed the use of a dipoles comforting Schottky (DCS) junction in the above-identified IEDM technical bulletin in the introductory part of the description. This dipole-caused SBH modulation effect is effective even when the high-concentration impurity layer of interest decreases in thickness to an extent that is less than or equal to several nanometers (nm) with advances in proportional scaling rules. Thus, it becomes possible to achieve an ultrathin metal/semiconductor junction with extra-low resistance.

However, in order to provide further enhanced performances of MISFET devices, a need is felt to further reduce the electrical resistance of the interface between a semiconductor substrate and metal silicide layers for use as the source/drain electrodes of MISFETs.

### SUMMARY OF THE INVENTION

In accordance with one aspect of this invention, a semiconductor device is provided which has a semiconductive substrate, and a p-type metal insulator semiconductor field effect transistor (“p-MISFET”) on the substrate. The p-MISFET includes a channel region in the substrate, a gate insulating film on the channel region, a gate electrode on the gate insulating film, and a pair of source and drain electrodes at both sides of the channel region. Each of the source/drain electrodes is formed of a nickel (Ni)-containing silicide layer. The p-MISFET further includes an interface layer at the substrate side of an interface between each source/drain electrode and the substrate. The interface layer contains therein at least one of magnesium (Mg), calcium (Ca) and barium (Ba).

In accordance with another aspect of the invention, a semiconductor device includes a semiconductor substrate, and an n-type MISFET (n-MISFET) on the substrate. The n-MISFET includes a channel region in the substrate, a gate insulating film on the channel region, a gate electrode on the gate insulating film, a pair of source/drain electrodes which are placed on the both sides of the channel region and which are each constituted from a Ni-containing silicide layer, and an interface layer which is provided on the substrate side of an interface between the substrate and each source/drain electrode and which contains therein at least one of selenium (Se) and tellurium (Te).

In accordance with a further aspect of the invention, a method for fabricating a semiconductor device having a p-MISFET on a semiconductive substrate is provided. This fabrication method includes the steps of forming a gate insulating film on the substrate, forming a gate electrode on the gate insulating film, depositing on the substrate a Ni-containing metal film, performing first thermal processing for causing the metal film to react with the substrate to thereby form a metal silicide layer on the both sides of the gate electrode, ion implanting any one of magnesium (Mg), calcium (Ca) and barium (Ba) into the metal silicide layer, and performing second thermal processing for segregating any one of Mg, Ca and Ba to the substrate side of an interface between the substrate and the metal silicide layer.

In accordance with another further aspect of the invention, a method of fabricating a semiconductor device having an n-MISFET on a semiconductive substrate is provided. This fabrication method includes the steps of forming a gate insulating film on the substrate, forming a gate electrode on the gate insulating film, depositing on the substrate a Ni-containing metal film, performing first thermal processing for causing the metal film to react with the substrate to thereby form a metal silicide layer on the both sides of the gate electrode, ion implanting any one of selenium (Se) and tellurium (Te) into the metal silicide layer, and performing second thermal processing for segregating any one of Se and Te to the substrate side of an interface between the substrate and the metal silicide layer.

### BRIEF DESCRIPTION OF THE DRAWINGS

FIG. 1 is a diagram illustrating, in cross-section, a semiconductor device in accordance with first embodiment of the present invention.

FIG. 2 is a diagram showing calculation results of a total energy in the case of a magnesium (Mg) atom being trapped at a nearby portion of the interface between a nickel silicide (NiSi) layer and a silicon (Si) layer.

FIG. 3 is a graph showing calculation results of a local density of states (LDOS).

FIG. 4 is a diagram showing a dipole model used in the process of calculating a generation energy.

FIG. 5 is a graph showing a relation of a modulation width Δφ_{b} of Schottky barrier height (SBH) and an energy of dipole to be formed.

FIG. 6 is a graph showing a plot of energy difference ΔE₂ versus covalent bond radius Rₐ of impurity atoms.

FIGS. 7 through 14 illustrate, in cross-section, some of major process steps in the manufacture of the semiconductor device shown in FIG. 1.

FIG. 15 is a graph showing calculation results of generation energy values of respective atoms.

FIG. 16 is a diagram showing a distribution curve of impurity atom to be formed by co-doping.

FIG. 17 is a diagram depicting, in cross-section, a structure of main part of a semiconductor device in accordance with another embodiment of this invention.

FIG. 18 is a diagram showing a cross-sectional structure of a semiconductor device in accordance with another embodiment of the invention.

FIGS. 19 to 26 illustrate, in cross-section, some major process steps in the manufacture of the semiconductor device shown in FIG. 18.

FIG. 27 shows a cross-sectional structure of a semiconductor device in accordance with another embodiment of this invention.

FIG. 28 is a cross-sectional view of a semiconductor device in accordance with another embodiment of the invention.

FIGS. 29 to 36 depict, in cross-section, some major steps in the manufacture of the semiconductor device shown in FIG. 28.

FIG. 37 is a sectional view of one typical structure of a currently available MISFET.

FIG. 38 is an energy band diagram of Schottky junction between a silicide film and Si layer.

FIG. 39 is a graph showing a difference in curvature of Si layer's band due to a difference of impurity concentration.

FIG. 40 is a diagram showing a prior known process of forming a NiSi layer.

FIGS. 41A and 41B are graphs each showing secondary ion mass spectrometry (SIMS) observation results of NiSi/Si layer interface by means of an impurity pre-doping process.

FIG. 42 is a graph showing a process flow of the impurity predoping process.

FIG. 43 is a graph showing SIMS observation results of NiSi/Si layer interface by means of the impurity predope process.

FIG. 44 is a graph showing a plot of boron (B) concentration of an interface versus anneal temperature.

FIG. 45 is a diagram showing energy calculation results in the case of a Si atom being substituted by B atom.

FIG. 46 is a diagram for explanation of a process of segregation of B atom in the impurity predope process.

FIG. 47 is a graph showing calculation results of Schottky barrier height (SBH).

FIG. 48 is a graph showing a relation of SBH modulation width versus B impurity concentration at an interface.

FIG. 49 is a diagram for explanation of SBH modulation by dipole.

### DETAILED DESCRIPTION OF THE EMBODIMENTS

Semiconductor devices and fabrication methods thereof in accordance with currently preferred embodiments of the present invention will be described with reference to the accompanying figures of the drawing below.

### First Embodiment

A semiconductor device of this embodiment is the one that has on a semiconductive substrate a p-type metal insulator semiconductor field effect transistor (MISFET). This p-type MISFET is structured to include a channel region in the semiconductor substrate, a gate insulating film which is formed on the channel region, a gate electrode that is formed on the gate insulating film, a pair of spaced-apart source and drain electrodes on the both sides of the channel region, which are each formed by a silicide layer that contains nickel (Ni), and an interface layer which is formed on the semiconductor substrate side of an interface between the source/drain electrode and the semiconductor substrate and which contains therein magnesium (Mg).

The p-MISFET of this embodiment is effectively reduced in electrical interface resistance of the source/drain electrodes owing to modulation of Schottky barrier height (SBH) due to the presence of the interface layer. By this interface resistance reduction, the pMISFET is improved in driving ability or “drivability” thereof. Thus, it is possible for this embodiment to enhance the performance of a semiconductor device of the type having at least one pMISFET.

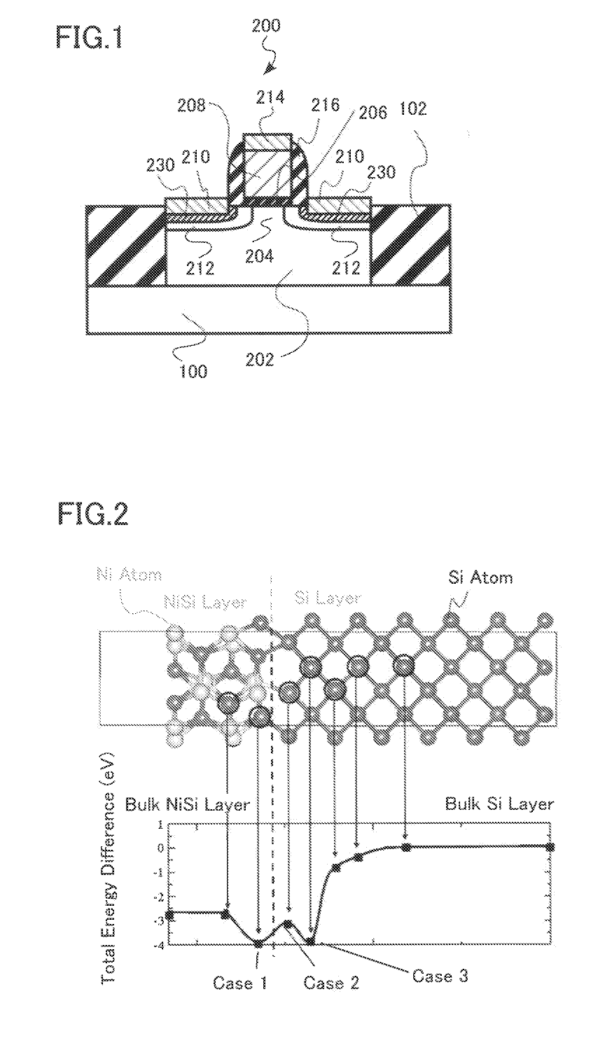

See FIG. 1. This diagram illustrates, in cross-section, a structure of main part of the semiconductor device of this embodiment. This semiconductor device has a p-type semiconductor substrate 100 which is made of silicon (Si) with boron (B) being doped to a concentration of about 1×10¹⁵ atoms per cubic centimeter (/cm³), and a p-type MISFET 200 on this substrate. The p-type MISFET 200 is formed in an n-type well region (n-well) 202, which is formed in a top surface of Si substrate 100. This semiconductor device also has an device isolation region 102 for electrical separation of n-well 202 in Si substrate 100. An example of the device isolation region 102 is a shallow trench isolation (STI) layer which may be made of a buried silicon oxide (SiOₓ) film.

The p-type MISFET 200 also has a channel region 204 on the Si substrate 100, a gate insulating film 206 which is formed on the channel region 204, and a gate electrode 208 formed on the gate insulating film 206. On the both sides of the channel region 204, source and drain electrodes are formed, which are structured from a silicide layer 210 made of nickel silicide (NiSi), as an example. On the substrate side of an interface between the source/drain electrode and Si substrate 100, an interface layer 230 is formed, which contains therein magnesium (Mg). Between the interface layer 230 and channel region 204, a p-type diffusion layer 212 is formed, into which an impurity of boron (B) is doped to a concentration of about 1×10²⁰ atoms/cm³, for example. Other examples of the p-type impurity to be doped into this p-type diffusion layer 212 include aluminum (Al) and indium (In) atoms.

On the gate electrode 208 of p-type MISFET 200, a gate silicide layer 214 is formed, which is made of NiSi, for example. A sidewall insulating film 216 is formed on the both side faces of the gate electrode 208, which is made of silicon nitride as an example.

An explanation will be given of interface resistance reduction capability or “reducibility” of the source/drain electrode due to the Mg-containing interface layer 230. For explanation of this function, an impurity distribution at the interface between NiSi layer and Si layer was theoretically analyzed. A calculation method used therefor was a spin-polarized generalized gradient approximation (SP-GGA) technique at a point which exceeds local density all-purpose function approximation, with spin polarization being also considered therein.

FIG. 2 is a diagram showing calculation results of a total energy of a crystal structure in the case of Mg atoms having been entered to Si substitution positions in vicinity to the interface between NiSi and Si layers. A reference (0 value) of the energy used here is an energy in case Si atoms of a bulk Si layer are replaced by impurity atoms—i.e., in the case of a plot at the right hand part of a graph of FIG. 2. As apparent from this graph, the energy becomes the highest in the case of Si atoms being substituted by Mg atoms in the bulk Si layer. This suggests that Mg atoms are less in activation capability within the bulk Si layer.

It has been traditionally reported that Mg atoms form the so-called deep level at an energy higher by 0.34 eV than the valence band of a bulk Si layer whereby these atoms are rarely activatable so that these do not behave as effective acceptors in any way. The calculation results of FIG. 2 are an evidence supporting this report. As Mg atoms in the bulk Si layer are less in activatability, it is hardly expectable for Mg atoms to form in the bulk Si layer a heavily impurity-doped layer for supplying carriers such as shown in FIG. 39 to thereby effectively lower the Schottky barrier height (SBH).

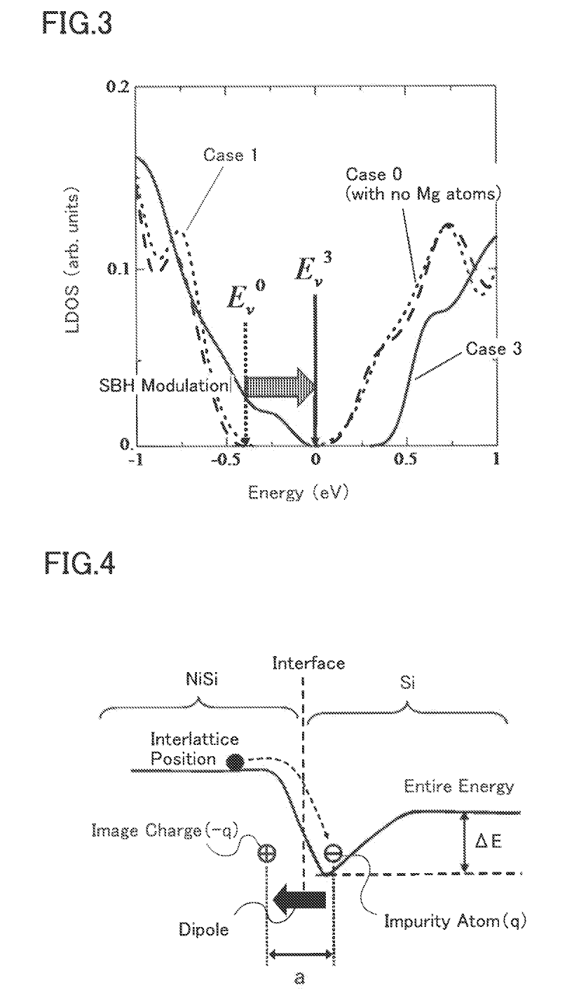

As shown in the graph of FIG. 2, the energy becomes the most stable in case No. 1 and case No. 3. FIG. 3 is a graph showing calculation results of local density of states (LDOS) in the cases shown in FIG. 2. In the case No. 3 where Mg atoms enter to the Si side of an interface, the modulation effect of Schottky barrier height (SBH) for holes becomes approximately 0.4 eV. Accordingly, use of Mg atoms makes it possible to obtain a significant SBH modulation effect when compared to the case of using B atoms, which are widely-used popular dopants for p-MISFETs. This is considered to be owing to the fact that Mg atoms tend to form larger dipoles at the interface. It is believed that such larger dipoles are formed by Mg atoms than by B atoms because Mg belongs to Group II in the periodic table whereas B is a III-group element, wherein the II-group element, Mg, is greater than the III-group element, B, in difference of valence number from the atoms of Si, which is a group-IV element.

As has been stated above, Mg atoms exist on the Si side of NiSi/Si interface and form an interface layer, thereby permitting generation of significant SBH modulation effect. In addition, such the interface layer offers enhanced energetic stability, it becomes possible to readily form a dipoles comforting Schottky (DCS) junction. Furthermore, in the illustrative embodiment device, an energy band curvature effect and/or image charge effect takes place due to the presence of the p-type impurity layer which contains B, Al or In. This facilitates the interface resistance reduction more effectively. In particular, the p-type impurity layer which is formed between the interface layer 230 that is high in carrier transit/passage density and the channel region 204 greatly contributes to improvements in drivability of p-MISFET 200 shown in FIG. 1.

It is noted that the Mg impurity contained in the interface layer 230 may be replaced by other suitable II-group elements, such as calcium (Ca), barium (Ba) or else. Alternatively, more than two of these elements, i.e., Mg, Ca and Ba, may be contained in this layer. A reason of this is as follows. Firstly, an attempt was made to perform energy calculations in cases where impurity atoms other than Mg and B, such as aluminum (Al), arsenic (As) and indium (In), enter to Si substitution positions. FIG. 4 shows a dipole model, which was used in the calculation process. As shown herein, let ΔE be a difference between energy when an impurity atom enters into a bulk Si layer and an energy when the atom enters to an interface thereof. Let ΔE₁ be an energy of a dipole to be formed by the entry of such impurity atom to the interface. Let ΔE₂ be a difference of ΔE₁ from ΔE. Then, the following equations are given:

$$Δ {E}_{1} = \frac{ɛ {d}^{2}}{4 π {a}^{3}} {Δφ}_{b}^{2} , \qquad ( 1 )$$

ΔE₂=ΔE−E₁. (2)

In the above, d is the lattice constant of a bulk Si, ∈ is the dielectric constant of bulk Si, π is the ratio of the circumference of a circle to its diameter, a is the distance between an impurity atom and image charge, and Δφ_{b} is the SBH modulation width.

The energy difference ΔE is equal to ΔE₁ plus ΔE₂. So, in order to increase the value of ΔE, it is preferable to choose an appropriate kind of impurity atoms that cause both ΔE₁ and ΔE₂ to increase in value at a time. ΔE₁ is obtainable by substituting into Equation (1) the SBH modulation width Δφ_{b} obtained from LDOS. The relation of Δφ_{b} and ΔE₁ is shown in FIG. 5. As apparent from this graph, ΔE₁ is proportional to a square value of Δφ_{b}. Basically, the greater the valence number of impurity atom (i.e., its element group number in the periodic table), the greater the Δφ_{b} value. Accordingly, in the p-MISFET 200 shown in FIG. 1, the value of ΔE₁ becomes the largest in the case where Mg with its valence number being greater than that of B is chosen as the impurity atom to be doped into the interface layer 230.

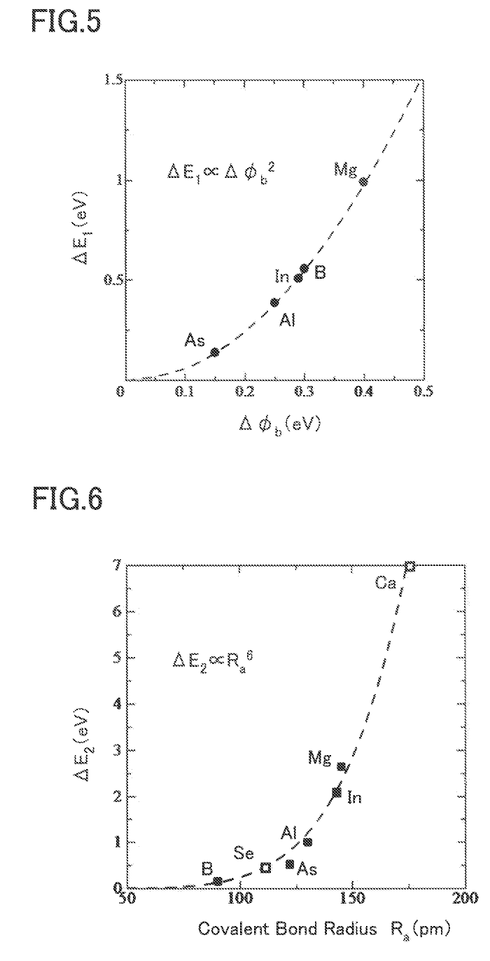

FIG. 6 is a graph showing a plot of ΔE₂ versus covalent bond radius, wherein ΔE₂ was obtained from the above-noted Equation (2). In this graph, black-painted rectangular marks indicate the actually calculated values. ΔE₂ is proportional to the six-time self-multiplied value of the covalent radius of impurity atom, i.e., the sixth power thereof. This indicates that an atom with a larger covalent radius is more easily enterable into the interface. More specifically, the entry or “invasion” of such large atom results in alleviation of distortions at NiSi/Si interface, which leads to an increase in energetic stability. Thus, it is suggested that for the impurity atom with large bond radius, the solid solubility limit of an impurity atom at NiSi/Si interface increases more appreciably when compared to that for a bulk.

It can thus be said that a desirable approach to realizing the ideal DCS junction is to choose as the impurity for interface layer a specific kind of impurity atoms with both ΔE₁ and ΔE₂ becoming larger in value—more specifically, atoms of the II-group or VI-group element having its covalent bond radius substantially equal to or larger than that of Si atoms (118 picometers (pm)). Typical examples of such the impurity atom preferable for p-MISFETs include but not limited to Mg (145 pm), Ca (174 pm), and Ba (198 pm). For n-MISFETs, examples of the impurity atom are Se (117 pm) and Te (135 pm). Theoretically, these atoms are energetically stable on the Si layer side of NiSi/Si interface and, at the same time, significant in dipole-caused SBH modulation effect.

In this embodiment device, a total concentration of Mg, Ca and Ba in the interface layer is preferably set to 1×10²¹ atoms/cm³ or more. With this specific impurity concentration setting, the resulting SBH modulation effect becomes nearly equal to 0.4 eV. This makes it expectable to obtain more significant interface resistance reduction effect than in the case of using a III-group element, such as B or else, as suggested by the calculation results.

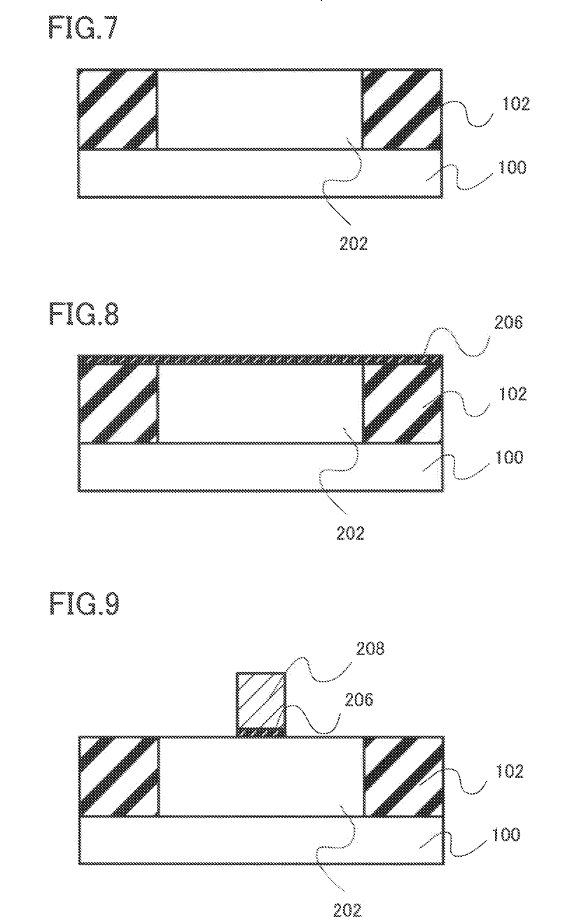

Next, an explanation will be given of a method of fabricating the semiconductor device having the p-MISFET 200 shown in FIG. 1 with reference to FIGS. 7 to 14 below. This fabrication method also embodying the invention includes the steps of forming a gate insulating film on a semiconductive substrate, forming a gate electrode on the gate insulating film, depositing a Ni-containing metallic film on the semiconductor substrate, performing first thermal processing for reaction of this metal film with the semiconductor substrate to thereby form a metal silicide film on the both sides of the gate electrode, ion implanting Mg atoms into the metal silicide layer, and performing second thermal processing for causing the doped Mg atoms to exhibit segregation on the substrate side of an interface between the metal silicide and the semiconductor substrate.

First, as shown in FIG. 7, a silicon (Si) substrate 100 of the p-type conductivity is prepared. This Si substrate has a (100) crystal plane on its top surface. In this (100) plane, a chosen impurity, such as boron (B), is doped to a predetermined concentration of about 10¹⁵ atoms/cm³, for example. In the surface of this p-Si substrate 100, a shallow trench isolation (STI) region 102 for device isolation is formed. This STI region may typically be a film of silicon oxide (SiO_{X}, e.g., SiO₂). Thereafter, an impurity of phosphorus (P) is doped by ion implantation techniques to thereby form an n-type well region 202. Next, as shown in FIG. 8, a gate insulating film 206 made of SiO₂ or else is formed on the Si substrate 100 to a thickness of about 1 nanometer (nm), which is the value converted into an equivalent oxide thickness (EOT).

Then, as shown in FIG. 9, a polycrystalline silicon film for later use as the gate electrode 208 is formed on the gate insulating film 206 by low pressure chemical vapor deposition (LPCVD) techniques to a thickness of about 100 to 150 nm. Then, lithography and reactive ion etch (RIE) techniques are used to pattern the gate insulating film 206 and gate electrode 208 in such a way as to have a gate length of 30 nm, or more or less. When the need arises, post-oxidation of 1 to 2 nm is performed.

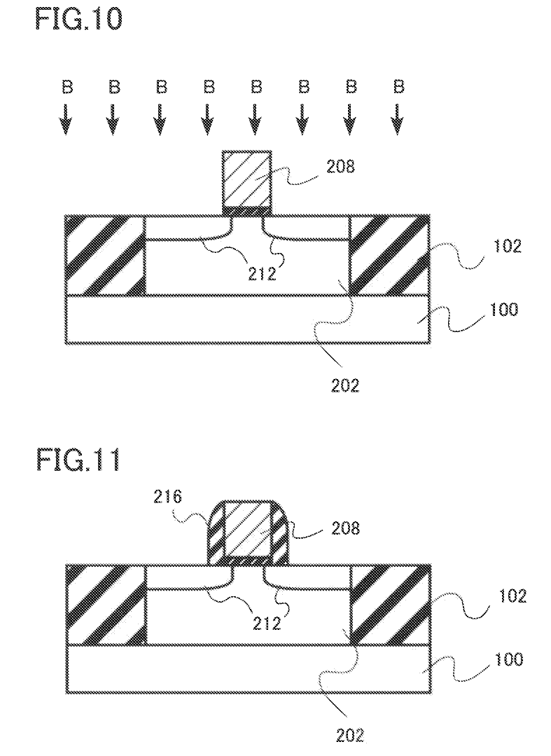

Next, as shown in FIG. 10, with the gate electrode 208 being used as a mask, a boron (B) impurity is introduced by ion implantation into the Si substrate 100, thereby to form a pair of spaced-apart p-type impurity diffusion layers 212 having a concentration of about 1×10²⁰ atoms/cm³. Note here that this ion implantation may also be carried out after a sidewall insulating film formation process to be performed later.

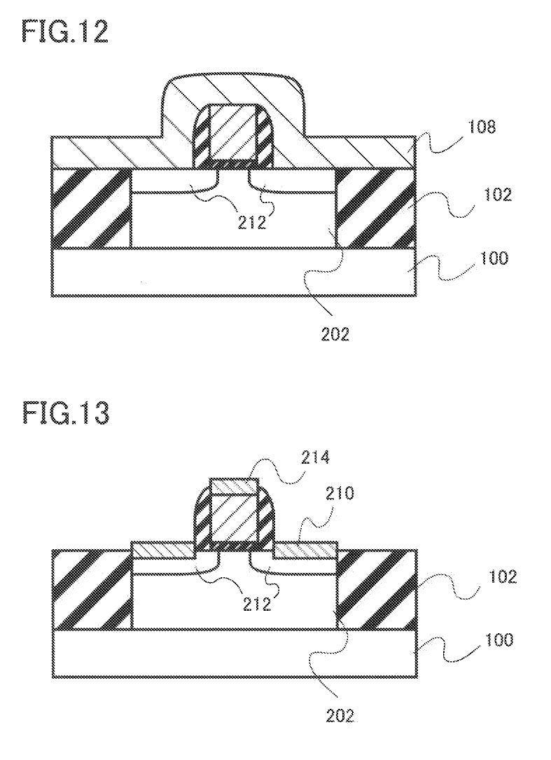

Next, a silicon nitride (SiNₓ) film is formed by LPCVD to a thickness of about 8 nm. Then, RIE-based etch-back is performed to selectively remove this film while letting only portions remain on the side surfaces of the gate electrode 208, thereby forming a sidewall insulating film 216 as shown in FIG. 11. Next, as shown in FIG. 12, a nickel (Ni) film 108 is formed by sputtering on Si substrate 100 to a thickness of about 10 nm. Specifically, this Ni film 108 deposited is in contact with the source and drain regions of p-MISFET.

Thereafter, as shown in FIG. 13, “first” thermal processing, such as rapid thermal annealing (RTA), is performed at a temperature of 500° C. for 30 seconds to silicidize the Ni film 108 to thereby form a nickel silicide (NiSi) film 210 having a thickness of about 20 nm. At this time, a gate silicide layer 214 is formed also on the gate electrode 208. Thereafter, a chemical solution is used to remove extra unreacted portions of Ni film 108. The resulting parts of NiSi layer 210 are for later use as the source and drain electrodes of p-MISFET.

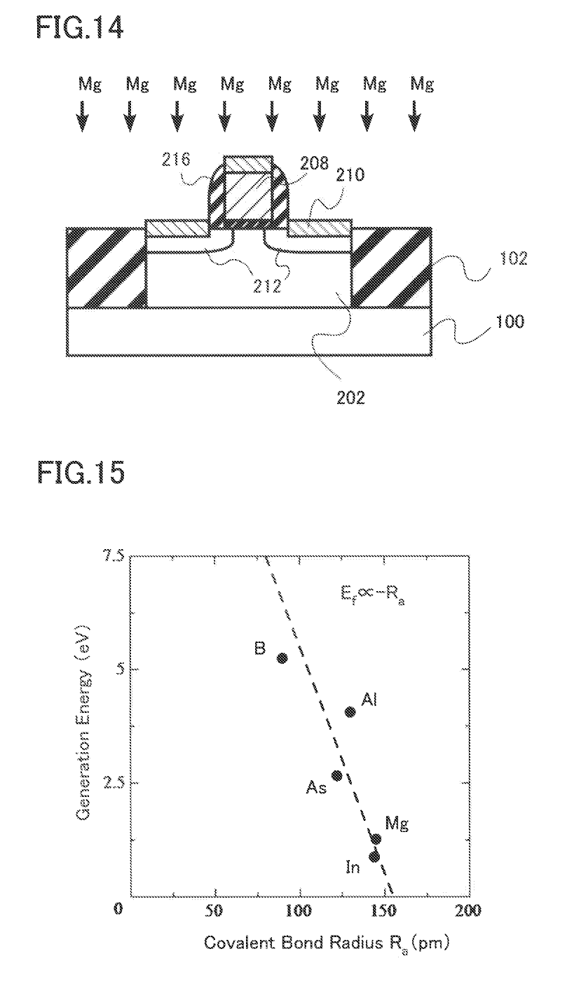

Next, as shown in FIG. 14, Mg atoms are introduced into the NiSi layer 210 by ion implantation with the gate electrode 208 and sidewall insulating film 216 being used as a mask. Preferably, process conditions of this ion implantation are set up to ensure that Mg atoms introduced have a distribution of concentration having a profile with its peak entering to inside of the NiSi layer 210. This enables the Mg atoms to exhibit effective segregation by a process of thermal processing to be executed later, thereby to further increase the impurity concentration of Mg interface layer.

Subsequently, “second” thermal processing, e.g., RTA baking, is performed at 550° C. for 30 seconds. By this baking, Mg atoms residing within the NiSi layer 210 are segregated to the substrate side of an interface between Si substrate 100 and NiSi layer 210 based on the above-stated impurity post-doping process principle so that a Mg-containing interface layer 230 is formed as shown in FIG. 1.

The formation of this Mg-containing interface layer 230 is affirmable by use of secondary ion mass spectroscopy (SIMS) methodology. Three-dimensional (3D) atomic probe methods are also employable: if this is the case, it is possible to affirm the presence of the interface layer 230 more accurately.

In accordance with the above-stated semiconductor device fabrication method embodying the invention, it is possible to segregate Mg atoms on the substrate side of NiSi/Si layer interface at which Mg atoms become energetically stable, thereby enabling successful formation of the heavily Mg-doped interface layer 230. Thus, it becomes possible to appreciably reduce the electrical interface resistance of the source/drain electrodes of p-MISFET. This makes it possible to achieve a high-performance semiconductor device.

It should be noted that in the fabrication process, Ca or Ba impurity atoms are employable in place of Mg. In this case also, similar results are obtainable concerning the formation of the intended high-concentration interface layer. This can be said because these impurity atoms also are such that energetically stable substitution positions are present on the substrate side of the interface between NiSi and Si layers in a similar way to Mg atoms.

It is also noted that in the embodiment semiconductor device and its fabrication method, it is desirable to add platinum (Pt) to the NiSi layer for use as the source/drain electrode. With this additional Pt doping, it is possible to suppress unwanted increase in junction leakage otherwise occurring due to abnormal diffusion of extra Ni atoms in NiSi layer toward the transistor channel part. Preferably, the amount of Pt to be contained in Ni film is set to fall within a range of from 5 to 10 atomic percent (at %). If the Pt concentration goes below this range, the abnormal diffusion of Ni atoms begins to decrease; if it goes beyond the range, there is the risk of an increase in fabrication costs due to the use of Pt, which is a highly expensive material.

### Second Embodiment

A semiconductor device fabrication method in accordance with another embodiment of this invention is similar to the above-stated fabrication method except that the process of ion implanting Mg atoms into NiSi layer prior to the second thermal processing is modified so that an impurity of boron (B), aluminum (Al) or indium (In) is additionally doped thereinto simultaneously—in other words, Mg atoms and B, Al or In atoms are doped together or “co-doped” into the NiSi layer. Accordingly, its duplicative explanations will be eliminated herein for brevity purposes.

More specifically, the fabrication method of this embodiment is substantially the same as the aforementioned first embodiment as far as its process steps up to that shown in FIG. 13 are concerned. Then, at the step shown in FIG. 14 of the first embodiment for Mg ion implantation, an additional impurity, such as B, Al or In atoms, is doped by ion implantation into the NiSi layer 210. Thereafter, the second thermal processing is applied to the resultant device structure to thereby fabricate a semiconductor device which is substantially the same as that shown in FIG. 1.

According to the semiconductor device fabrication method of this embodiment, it becomes possible by execution of the codoping of Mg and B atoms along with Al or In atoms to form the intended interface layer with high concentration as will be described in detail below.

As shown in FIG. 2, Mg atoms become most stable on Si side of the interface. However, in a bulk, Mg atoms are more stable on NiSi layer side than on Si layer side. Accordingly, as in the first embodiment, it is predicted that an appreciable amount of Mg atoms behave to enter to the NiSi layer side even when using an impurity post-doping process.

As shown in the case 1 in FIG. 3, Mg atoms that have entered to NiSi layer side exhibit no SBH modulation effects. For this reason, Mg atoms that contribute to SBH modulation effect decrease in number, resulting in the SBH modulation effect being weakened. In this respect, when doping into the NiSi layer both Mg atoms and a specific kind of impurity atoms that behave to more easily enter to a bulk NiSi layer than Mg atoms, it becomes possible to collect an increased number of Mg atoms at Si layer side of NiSi layer interface. This makes it possible to enhance the SBH modulation effect.

The impurity atom that enters to a bulk NiSi layer more easily than Mg atom is the one that is greater than Mg atom in generation energy when entering to a Si substitution position of bulk NiSi layer. In the case where an impurity has entered to Si substitution position of NiSi layer, the generation energy E_{f}^{Si} is defined by:

E_{f}^{Si}=−Ea−Eb+Ec+Ed, (3)

where Ea is the energy of a cell structure with one Si atom being substituted by an impurity atom in a unit cell having thirty two (32) NiSi molecules, Eb is the energy of one Si atom in a bulk, Ec is the energy of a cell structure having 32 NiSi molecules, and Ed is the energy of an impurity atom in a vacuum.

See FIG. 15, which graphically shows calculation results of the generation energy of respective kinds of atoms based on the equation above. It is apparent from this graph that the generation energy linearly increases with a decrease in covalent bond radius of atom. Therefore, by performing the codoping of B, Al or In atoms that are less in covalent radius than Mg atoms as in this embodiment, it is possible to collect together an increased number of Mg atoms at Si layer side of the interface. This makes it possible to further lower the electrical resistance of NiSi layer interface.

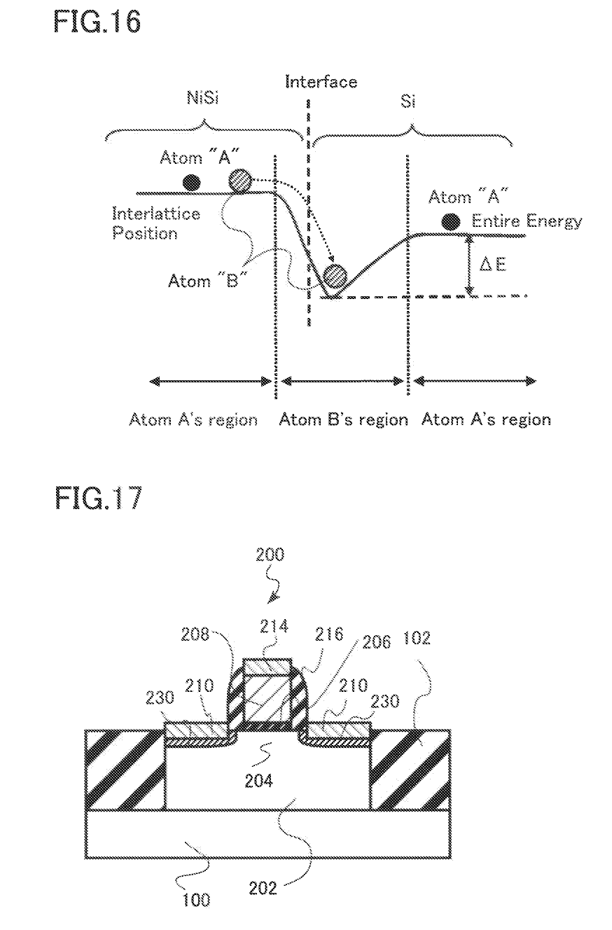

FIG. 16 shows one typical distribution of impurity atom, which is formed by the codoping. Generally, when performing the codoping of an atom “A” that is relatively less in covalent bond radius and an atom “B” that is large in covalent radius, the distribution curve such as shown in FIG. 16 is obtainable. To obtain this distribution, it is needed to introduce the atom B into Si layer side of the interface. To do this, the impurity post-doping process as in this embodiment is effectively employable. With the use of this process, the atom A that is larger in generation energy acts to bury a crystal defect in NiSi layer during diffusion of respective atoms within NiSi layer. This permits the atom B to gather at Si layer side of the interface more effectively.

Also importantly, B, Al or In atoms act as acceptors even when these are diffused into Si in the process of codoping. Thus, the energy band curvature effect and image charge effect shown in FIG. 39 take place. This enables the interface resistance to further decrease more effectively.

Preferably, B, Al or In atoms are ion-implanted prior to the ion implantation of Mg atoms. More specifically, before the ion implantation of Mg, Ca or Ba atoms into the metal silicide layer, B, Al or In ions are doped into this metal silicide layer. With this precedent ion implantation, B atoms or the like behave to diffuse first and then bury the substitution positions of NiSi layer, followed by the diffusion of Mg atoms thereafter. This makes it possible to collect together an increased number of Mg atoms on the Si layer side of the interface. The same goes with the case of Ca or Ba atoms being used in place of Mg atoms.

In this embodiment, similar results are obtained in the case of Ca or Ba atoms being used in place of Mg atoms.

### Third Embodiment

A semiconductor device in accordance with another embodiment of this invention is shown in FIG. 17, which depicts main part of it in cross-section diagram form. This device structure is characterized in that the source/drain electrode of a p-type MISFET has a Schottky barrier junction. This device is similar to the first embodiment stated supra in terms of the other structural features.

The semiconductor device having the p-MISFET shown in FIG. 17 is different from the device structure of FIG. 1 in that the former does not have the p-type impurity layer in the source and drain regions thereof. As previously stated, II-group element atoms which form the interface layer 230, such as Mg, Ca or Ba, are less activatable so that these hardly act as acceptors. Thus, it becomes possible for the transistor structure of FIG. 17 to reduce the interface resistance of the source/drain electrode by the presence of the interface layer 230 and, at the same time, improve the withstandability against short-channel effects owing to the omission of the p-type impurity layer.

Next, an explanation will be given of a fabrication method of the semiconductor device of FIG. 17. This fabrication method is similar to the second embodiment with the boron (B) ion implantation for p-type impurity layer formation being omitted and with the impurity atom for codope with Mg, Ca or Ba into NiSi layer being set to carbon (C) or fluorine (F), rather than B.

By codoping of C or F atoms, which are less in covalent bond radius than Mg, Ca and Ba, in place of B atoms also, it is possible to increase the impurity concentration of Mg, Ca or Ba in the interface layer. These atoms do not function as dopants within Si layer; thus, the short-channel effect of p-MISFET is hardly deteriorated even when such atoms are diffused into Si layer side by thermal processing or other similar baking processes. Another advantage of this embodiment is that C and F form no large dipoles at the interface so that there is no risk of weakening the dipole of interface layer which is formed by Mg or else that has entered to the Si side.

### Fourth Embodiment

Referring to FIG. 18, main part of a semiconductor device having an n-type MISFET in accordance with another embodiment of this invention is illustrated in cross-section. This n-MISFET has a channel region in the top surface of a semiconductor substrate, a gate insulating film which is formed on the channel region, a gate electrode formed on the gate insulating film, a pair of source and drain electrodes on the both sides of the channel region, which are formed of a Ni-containing silicide layer, and a selenium (Se)-containing interface layer. The Se-containing interface layer is formed on the substrate side of an interface between the source/drain electrode and the semiconductor substrate.

The n-MISFET device shown in FIG. 18 is such that the source/drain electrode is effectively reduced in interface resistance owing to SBH modulation which is achievable by the presence of the interface layer, thereby improving the drivability thereof. Thus, according to this embodiment, it is possible to enhance the performance of a semiconductor device having such nMISFET.

More specifically, the semiconductor device of FIG. 18 is designed to have a p-type silicon (Si) substrate 100 with boron (B) being doped thereinto to a concentration of 1×10¹⁵ atoms/cm³, for example, and an n-MISFET 300 which is formed on this Si substrate. The nMISFET 300 is formed within a p-type well region 302 which is formed in the top surface of Si substrate 100. An device isolation region 102 is also formed in Si substrate 100. An example of this device isolation region 102 is a shallow trench isolation (STI) layer made of a buried silicon oxide film.

The nMISFET 300 has a channel region 304 in Si substrate 100, a gate insulator 206 which is formed on the channel region 304, and a gate electrode 208 that is formed on gate insulating film 206. Source and drain electrodes are formed at both sides of channel region 304, which are structured from a conductive layer 210 made of nickel silicide (NiSi), for example. An interface layer 330 which contains therein Se is formed on the substrate side of an interface between the source/drain electrode and the Si substrate. Between the Se-containing interface layer 330 and channel region 304, an n-type impurity diffusion layer 312 is formed, into which atoms of a chosen impurity, e.g., arsenic (As), are doped to a concentration of 1×10²⁰ atoms/cm³ as an example. The As impurity that is doped into this n-type diffusion layer may be replaced by phosphorus (P) or antimony (Sb) or else, when the need arises.

A gate silicide layer 214 made of NiSi is formed on the gate electrode 208 of nMISFET 300. On the both side surfaces of gate electrode 208, a sidewall insulating film 216 is formed. This film may be made of silicon nitrides.

As previously described, one desirable approach to achieving an ideal dipoles comforting Schottky (DCS) junction is to use a specific kind of atoms greater in both ΔE₁ and ΔE₂—more precisely, the II- or VI-group atoms that are nearly equal to or larger than Si atoms in covalent bond radius. For the n-MISFET, examples of such atoms are Se (117 pm) and Te (135 pm), which have their covalent radius values similar to or larger than that of Si atoms (118 pm). In this embodiment, by forming the Se-containing interface layer 330, reduction of the interface resistance is realizable. Similar interface resistance reducing effects are obtainable by use of Te in place of Se. Similar results are obtained by using Se and Te in combination. Furthermore, in this embodiment, the inclusion of the n-type impurity layer which contains P, As or Sb results in creation of band curvature and image charge effects; thus, it is possible to further effectively reduce the interface resistance. In particular, the n-type impurity layer that is formed between the channel region and the carrier passage density-enhanced interface layer contributes significantly to the improvement of MISFET drivability.

Preferably in this embodiment, the total concentration of Se and Te in the interface layer is set to 1×10²¹ atoms/cm³ or more. With this impurity concentration setting, it is expected to achieve significant reducibility of the interface resistance.

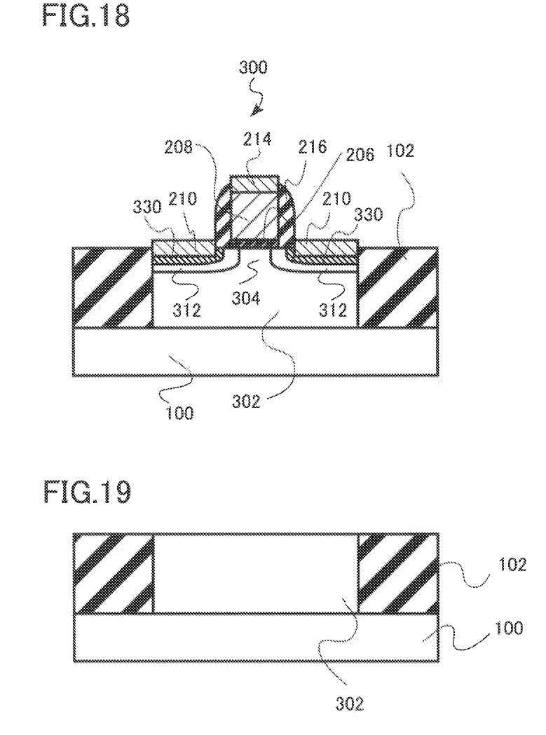

A method of fabricating the semiconductor device having the n-MISFET shown in FIG. 18 will next be described with reference to FIGS. 19 through 26 below. This fabrication method includes the steps of forming a gate insulating film on a semiconductor substrate, forming a gate electrode on the gate insulating film, depositing on the substrate a Ni-containing metal film, applying first thermal processing to the resultant device structure to thereby cause the metal film to react with the substrate for forming a metal silicide layer on both sides of the gate electrode, ion implanting Se in the metal silicide layer, and performing second thermal processing to thereby segregate the implanted Se atoms to the substrate side of an interface between the metal silicide layer and the semiconductor substrate.

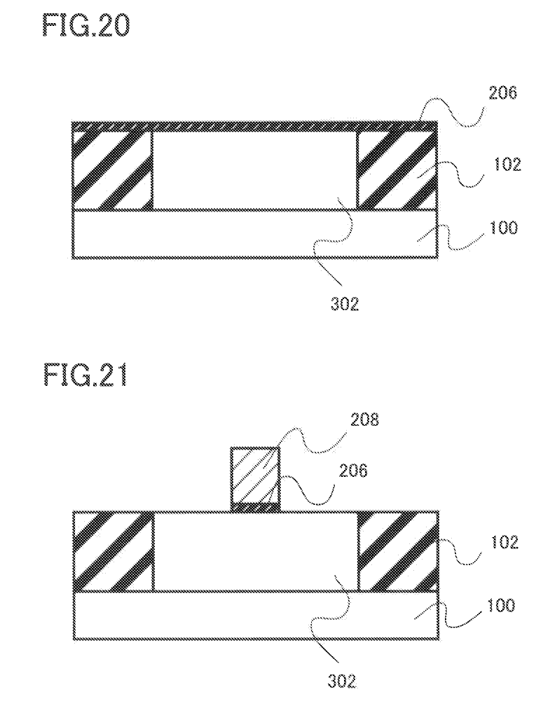

First, as shown in FIG. 19, a p-type silicon substrate 100 is prepared. This Si substrate has a top surface having a (100) plane, in which a boron (B) impurity being doped to a concentration of 10¹⁵ atoms/cm³, for example. Then, an STI device isolation region 102 made of silicon oxide is formed in Si substrate 100. Then, a p-type well region 302 is formed by ion implantation of a chosen impurity, e.g., B. Next, as shown in FIG. 20, a gate insulating film 206 is formed on Si substrate 100 to a thickness of about 1 nm in EOT. Film 206 may be a silicon oxide (SiOₓ) film or else.

Subsequently, as shown in FIG. 21, a poly-Si film for later use as the gate electrode 208 is formed by LPCVD on the gate insulating film 206 to a thickness of about 100 to 150 nm. Then, the gate insulating film 206 and gate electrode 208 are patterned by known lithography and RIE techniques. This gate electrode formed has a gate length of about 30 nm. Here, post-oxidation of 1 to 2 nm may be performed, when the need arises.

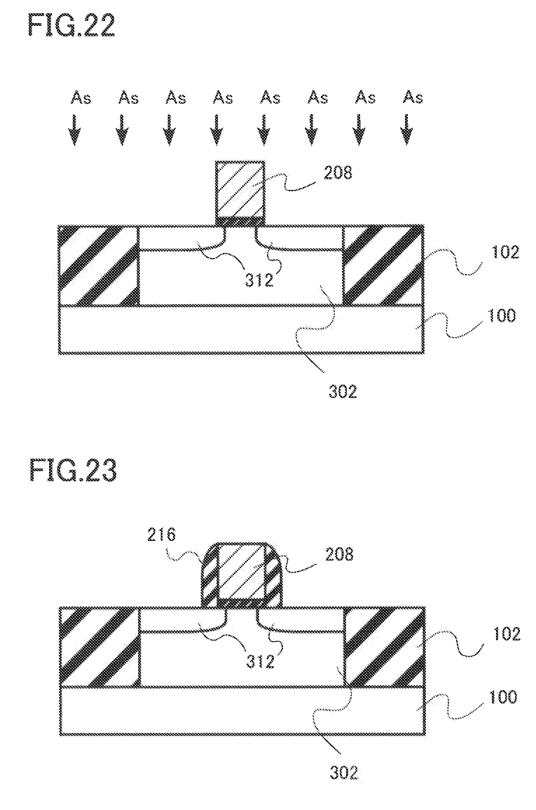

Next, as shown in FIG. 22, with the gate electrode 208 as a mask, an As impurity is doped by ion implantation into Si substrate 100 to thereby form a pair of n-type impurity diffusion layers 312 having a concentration of about 1×10²⁰ atoms/cm³. This ion implantation may alternatively be performed after having formed a sidewall insulating film at a later step.

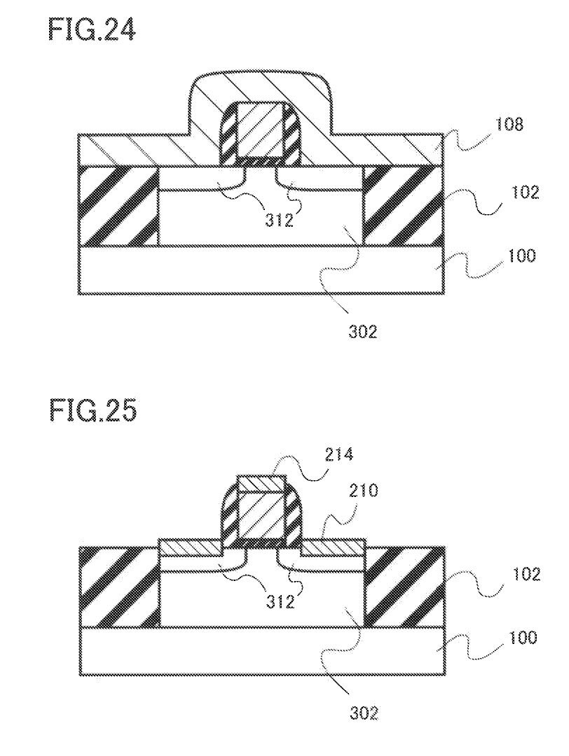

Next as shown in FIG. 23, a silicon nitride (SiNₓ) film is formed by LPCVD to a thickness of about 8 nm. Thereafter, RIE etch-back is applied, thereby selectively removing the SiNₓ film so that its portions are left only at sidefaces of gate electrode 208. This results in sidewall insulating film 216 being formed. Next as shown in FIG. 24, Ni film 108 with a thickness of about 10 nm is formed by sputtering on Si substrate 100. More specifically, this Ni film 108 is deposited in such a manner as to be in contact with the source and drain of n-MISFET.

Thereafter, the first thermal processing is applied to the resulting device structure. More specifically, as shown in FIG. 25, a 500° C., 30-sec rapid thermal anneal (RTA) is performed for silicidation of Ni film 108, thereby to form a NiSi layer 210 to a thickness of about 20 nm as an example. At this time, a gate silicide layer 214 is formed also on the gate electrode 208. Then, extra unreacted portions of Ni film 108 are removed away by use of a chosen chemical solution. The resultant NiSi layer 210 is for use as the source and drain electrodes of n-MISFET.

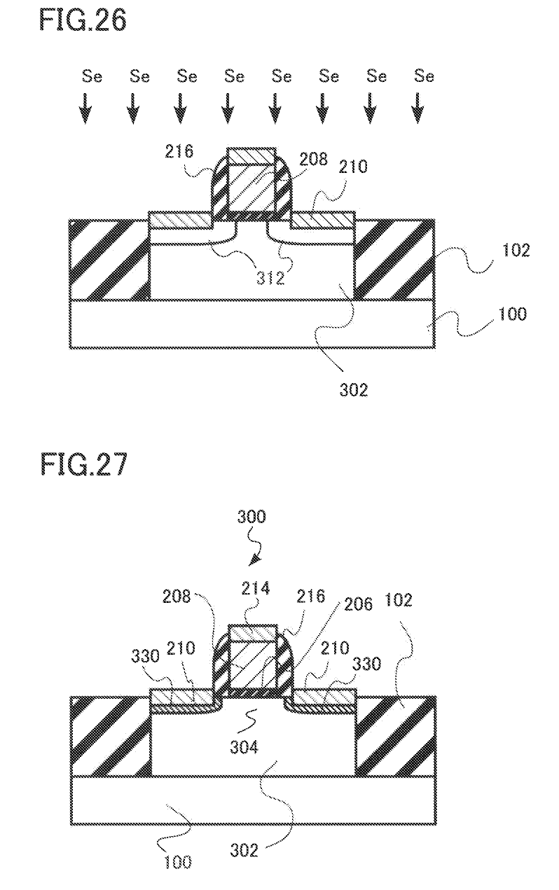

Next as shown in FIG. 26, with the gate electrode 208 and sidewall insulating film 216 being as a mask, a Se impurity is introduced by ion implantation into NiSi layer 210. Preferably, process conditions are set to ensure that the implanted Se atoms have a peak of concentration profile that enters to inside of NiSi layer 210 at the time immediately after completion of the ion implantation. With such the condition setup, it is possible to effectively segregate Se atoms by thermal processing to be later performed. Thus, it becomes possible to further increase the impurity concentration of Se interface layer.

Thereafter, RTA anneal is performed at 550° C. for about 30 seconds, as the second thermal processing. By this RTA process, Se atoms within NiSi layer 210 segregate to the substrate side of the interface between Si substrate 100 and NiSi layer 210 based on the principles of the impurity post-doping process as has been discussed previously, resulting in a Se-containing interface layer 330 being formed as shown in FIG. 18.

The fabrication of this Se-containing interface layer 330 is confirmable by using SIMS method. 3D atomic probe methodology is also employable. If this is the case, it is possible to make sure the presence of the interface layer 330 more accurately.

According to the n-MISFET device fabrication method also embodying the invention, it is possible to form, through effective segregation of Se atoms, the heavily Se concentrated interface layer on the substrate side of the Si/NiSi layer interface at which Se atoms become energetically stable. Thus it is possible to reduce the interface resistance of the source/drain electrodes of nMISFET, thereby enabling the semiconductor device having such nMISFET to offer enhanced performances.

It is noted that in the fabrication method stated above, the high-concentration interface layer formation are expectable by using Te in place of Se impurity. This can be said because Te atoms also are such that an energetically stable substitution position is on the substrate side of the NiSi/Si layer interface in a similar manner to Se atoms.

In the semiconductor device of this embodiment and its fabrication method, it is more preferable to add Pt to NiSi layer for use as the source/drain electrode, as in the case of the above-stated pMISFET device.

### Fifth Embodiment

A semiconductor device fabrication method in accordance with a further embodiment of this invention is similar to that of the fourth embodiment, except that the former is modified so that P, As or Sb atoms, along with Se atoms, are additionally doped by ion immolation into the NiSi layer prior to execution of the second thermal processing—in other words, Se atoms and P, As or Sb atoms are codoped together into NiSi layer.

This embodiment fabrication method is similar to that of the fourth embodiment as far as the process up to the step shown in FIG. 25 are concerned. At the fourth embodiment's step shown in FIG. 26, when introducing Se into NiSi layer 210 by ion implantation, P, As or Sb atoms are also ion-implanted thereinto simultaneously. Thereafter, the second thermal processing is applied, thereby forming a semiconductor device which is similar in structure to that shown in FIG. 18.

According to the fabrication method of this embodiment, it is possible by codoping Se atoms and P, As or Sb atoms into the NiSi layer to form the high-concentration interface layer. At this time, it is most effective to use, in particular, P atoms that are less in covalent bond radius than Se atoms.

According to this embodiment, Se atoms plus an impurity atom that readily enters to the bulk NiSi layer than Se atom are doped together into the NiSi layer. This makes it possible to collect an increased number of Se atoms at part on the Si layer side of the NiSi layer interface. Thus it is possible to enhance the SBH modulation effect.

Additionally, even if the P, As or Sb atoms are diffused into bulk Si during the codoping process, these act as donors, resulting in creation of the band curvature and image charge effects shown in FIG. 39. This may serve to reduce the interface resistance more effectively.

In this embodiment, it is preferable to dope P, As or Sb atoms by ion implantation prior to the ion implantation of Se atoms. More specifically, before Se or Te is ion-implanted into the metal silicide layer, P, As or Sb is ion-implanted into this layer. Use of this pre-doping process permits P, As or Sb atoms to behave to diffuse first, resulting in fulfillment of substitution positions of NiSi layer. This makes it possible to collect a greater number of Se atoms at the Si layer side of the interface. The same goes with the case of Se atoms being replaced by Te atoms.

In this embodiment, similar results may be obtained when using Te in place of Se.

### Sixth Embodiment

A semiconductor device having n-type MISFET in accordance with another embodiment of this invention is shown in FIG. 27 in sectional diagram form. This transistor structure is similar to that of the fourth embodiment shown in FIG. 18, with the source/drain electrode being modified to have Schottky junction.

The transistor structure of FIG. 27 is arranged to have no n-type impurity layers at its source and drain regions, unlike the structure of FIG. 18. As previously stated, VI-group element atoms forming the interface layer 300 here, such as Se or Te, are less in activatability so that these hardly function as donors. Thus, according to this embodiment, the interface resistance of source/drain electrode is reducible by the interface layer while at the same time eliminating the use of the n-type impurity layer. Thus, it becomes possible to improve the short-channel effect durability thereof.

A fabrication method of the nMISFET device shown in FIG. 27 is similar to the fifth embodiment, except that the As ion impurity for forming the n-type impurity layer is omitted and that the impurity atoms to be codoped with Se or Te into NiSi layer is carbon (C) or fluorine (F), rather than As or Sb.

Even when codoping C or F atoms that are less in covalent bond radius than Se and Te atoms in place of P, As or Sb, it is possible to increase the concentration of Se or Te atoms in the interface layer. These atoms do not function as dopants within Si layer. Accordingly, even if these diffuse to the Si layer side of interface due to thermal processing or else, the short-channel effect of nMISFET is hardly deteriorated. Another advantage of this embodiment is that C and F forms no large dipoles at the interface so that the dipoles of an interface layer to be formed by Se atoms that entered to Si side of the interface are hardly weakened.

### Seventh Embodiment

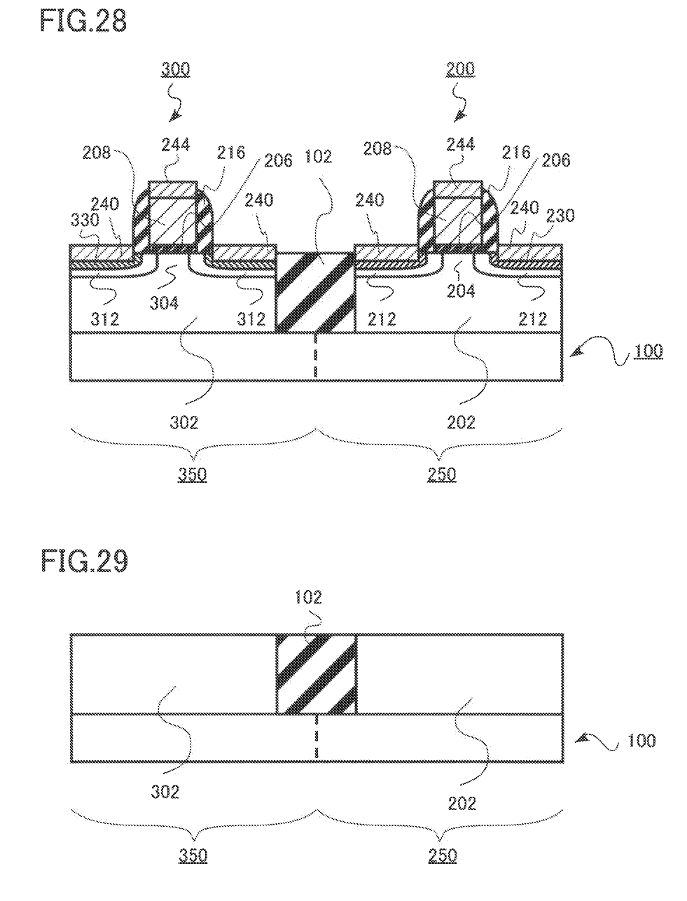

A semiconductor device having complementary metal insulator semiconductor field effect transistor (CMISFET) structure in accordance with a further embodiment of this invention is shown in FIG. 28 in sectional diagram form. This semiconductor device includes a p-type MISFET having an interface layer which contains Mg in an interface layer of the source/drain electrode and an n-type MISFET having an interface layer which contains Se in an interface layer of source/drain electrode thereof.

In the CMIS transistor device shown in FIG. 28, the p-MISFET 200 and n-MISFET 300 are formed on a top surface of silicon substrate 100. More specifically, pMISFET 200 is formed in n-type well region 202 which is formed in Si substrate 100. The nMISFET 300 is formed in p-type well region 302 that is formed in Si substrate 100.

An device isolation region 102 is formed at the boundary of the region in which pMISFET 200 is formed and the region in which nMISFET 300 is formed. This device isolation region may typically be a shallow trench isolation (STI) layer, such as a buried silicon oxide film.

The pMISFET 200 has a channel region 204 on Si substrate 100, a gate insulating film 206 which is formed on the channel region 204, and a gate electrode 208 which is formed on the gate insulating film 206. On the both sides of channel region 204, a pair of laterally spaced-apart source and drain electrodes are formed, each of which is structured from a silicide layer 240 that is made of a Pt-containing NiSi material. On both sides of channel region 204, a p-type impurity layer 212 is formed, into which atoms of a chosen impurity, e.g., boron (B), are doped to a concentration of 1×10²⁰ atoms/cm³. A Mg-containing interface layer 230 is formed at the substrate side of an interface between the source/drain electrode and the Si substrate.

On the gate electrode 208 of pMISFET 200, a gate silicide layer 244 is formed, which is made of Pt-containing NiSi as an example. On both sides of gate electrode 208, a sidewall insulating film 216 made of silicon nitride is formed.

The nMISFET 300 has a channel region 304 on the Si substrate 100, a gate insulating film 206 formed on the channel region 304, and a gate electrode 208 formed on the gate insulating film 206. On the both sides of the channel region 304, a pair of source and drain electrodes are formed, each of which is structured from a silicide layer 240 that is made of Pt-containing NiSi material. On both sides of channel region 204, an n-type impurity layer 312 is formed, into which a chosen impurity, e.g., arsenic (As), is doped to a concentration of 1×10²⁰ atoms/cm³. A Se-containing interface layer 330 is formed at the substrate side of an interface between the source/drain electrode and the Si substrate.

On the gate electrode 208 of nMISFET 300, a gate silicide layer 244 is formed, which is made of Pt-containing NiSi for example. On both sides of gate electrode 208, a sidewall insulating film 216 made of SiNₓ is formed.

The CMISFET device is such that each of its pMISFET and nMISFET is capable of being effectively reduced in electrical interface resistance of source/drain electrode by SBH modulation owing to the presence of the interface layer. Thus, both the pMISFET and nMISFET are increased in drivability. This makes it possible to achieve the intended CMIS transistor structure with enhanced performances.

An explanation will next be given of a fabrication method of the CMISFET device of FIG. 28 with reference to FIGS. 29 to 36 below.

First, as shown in FIG. 29, an STI element separation region 102 made of SiOₓ is formed in a p-Si substrate 100 having a (100) plane with a boron (B) impurity doped to a concentration of 10¹⁵ atoms/cm³, for example. This STI region 102 is formed at the boundary of a semiconductor region 250 in which a pMISFET will be formed and a semiconductor region 250 in which an nMISFET is to be later formed. Thereafter, an n-well 202 and p-well 302 are formed by ion implantation of chosen impurities, respectively.

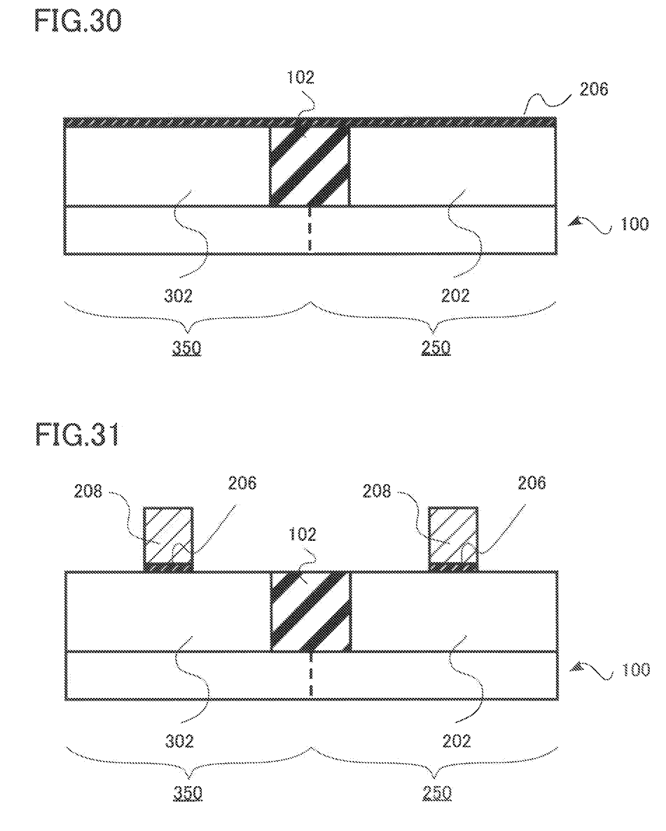

Next, as shown in FIG. 30, a SiOₓ film 206 for later use as the gate insulator is formed on the above-noted semiconductor regions 250 and 350 to a predetermined thickness of 1 nm in EOT. Then, as shown in FIG. 31, a poly-Si film for later use as the gate electrodes 208 is formed by LPCVD on the gate insulating film 206 to a thickness of 100 to 150 nm. Next, lithography and RIE techniques are used to form the patterned gate insulating film 206 and gate electrodes 208 in such a manner that the gate length becomes about 30 nm. If necessary, post-oxidation of 1 to 2 nm is performed.

Next, as shown in FIG. 32, with the gate electrode 208 and a patterned resist film (not shown) being used as a mask, a B impurity is introduced by ion implantation into the “first” semiconductor region 250 of Si substrate 100, thereby forming p-type impurity diffusion layers 212 having an impurity concentration of about 1×10²⁰ atoms/cm³, for example. Subsequently, with the gate electrode 208 and another patterned resist film (not shown) being used as a mask, an As impurity is doped by ion implantation into the “second” semiconductor region 350 of Si substrate 100 to thereby form p-type impurity layers 312 having an impurity concentration of about 1×10²⁰ atoms/cm³, as an example. This ion implantation may alternatively be performed after completion of a sidewall insulating film formation process to be later performed.

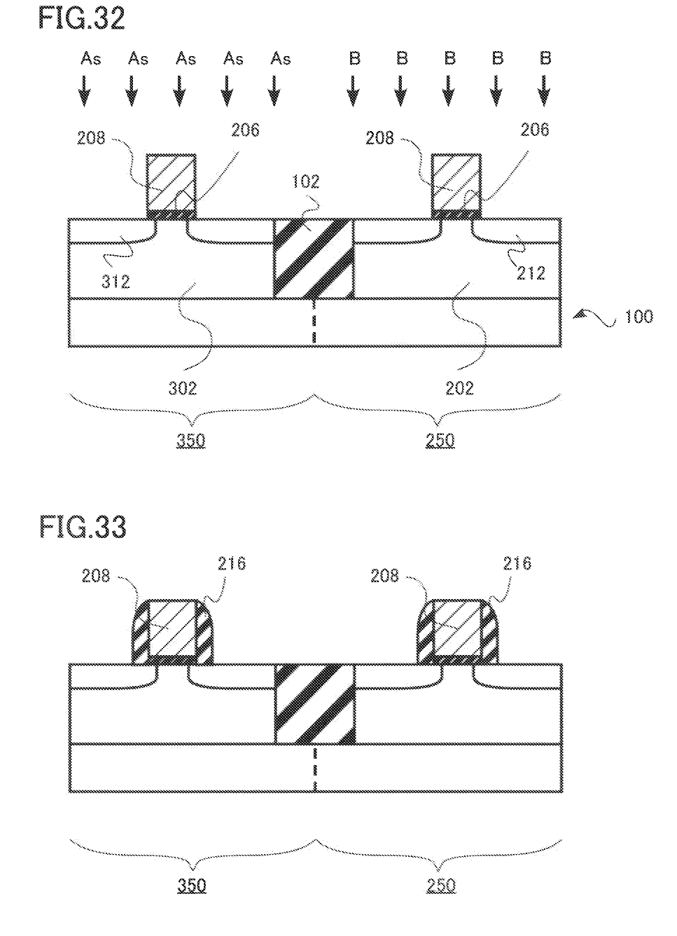

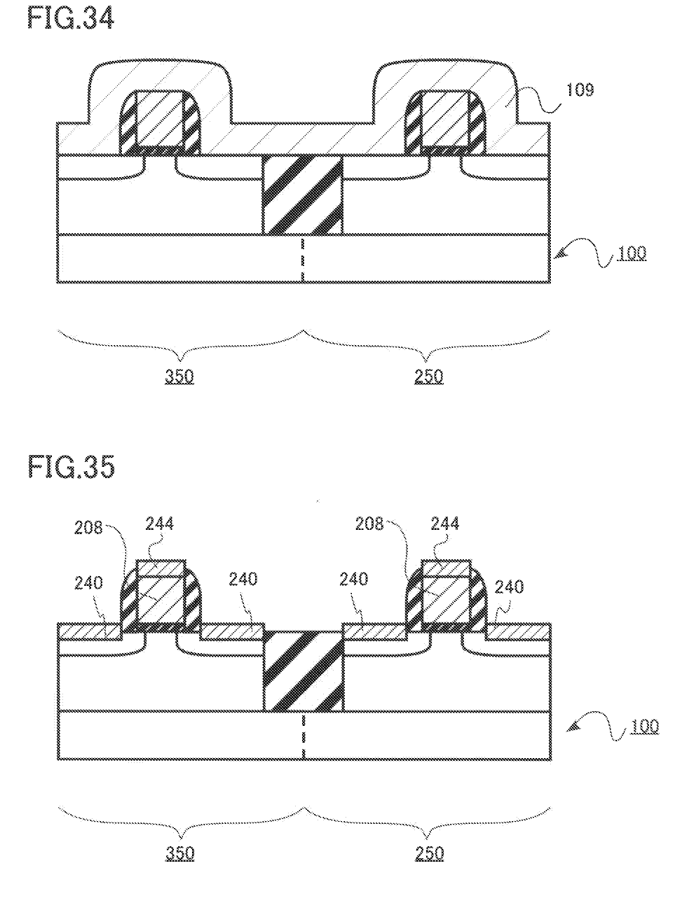

Next, as shown in FIG. 33, a SiNₓ film is deposited by LPCVD to a thickness of about 8 nm. Thereafter, this film is subjected to etch-back by RIE method in such a manner that the SiNₓ film partly resides on the side surface portions of the gate electrodes 208, thereby forming a sidewall insulating film 216. Next, as shown in FIG. 34, a Pt-containing nickel film 109 is formed by sputtering on Si substrate 100 in such a manner that the Pt-containing Ni film 109 is in contact with the source and drain regions of the pMISFET and nMISFET of CMISFET device.

Thereafter, as shown in FIG. 35, the resulting device structure is applied the first thermal processing. More specifically, rapid thermal annealing (RTA) is performed at 500° C. for 30 seconds for silicidizing Ni film 109, thereby to form a Pt-containing nickel silicide (NiSi) layer having a thickness of about 20 nm. At this time, a gate silicide layer 244 is also formed on a respective one of the gate electrodes 208. Then, a chemical solution is used to remove extra non-reacted portions of Ni film 109. The resultant portions of NiSi layer 240 are for use as the source and drain electrodes of pMISFET and nMISFET.

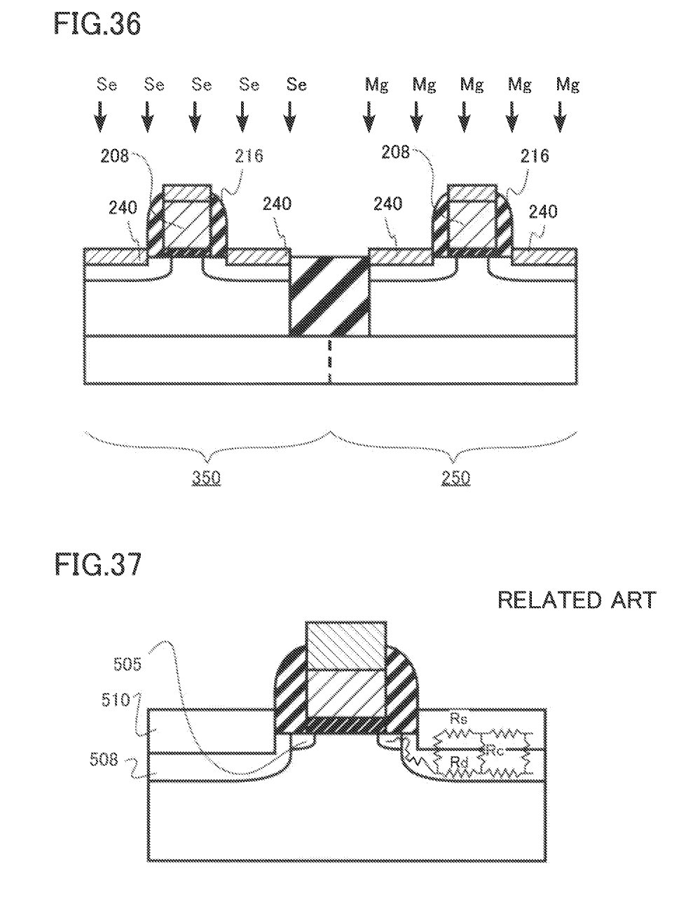

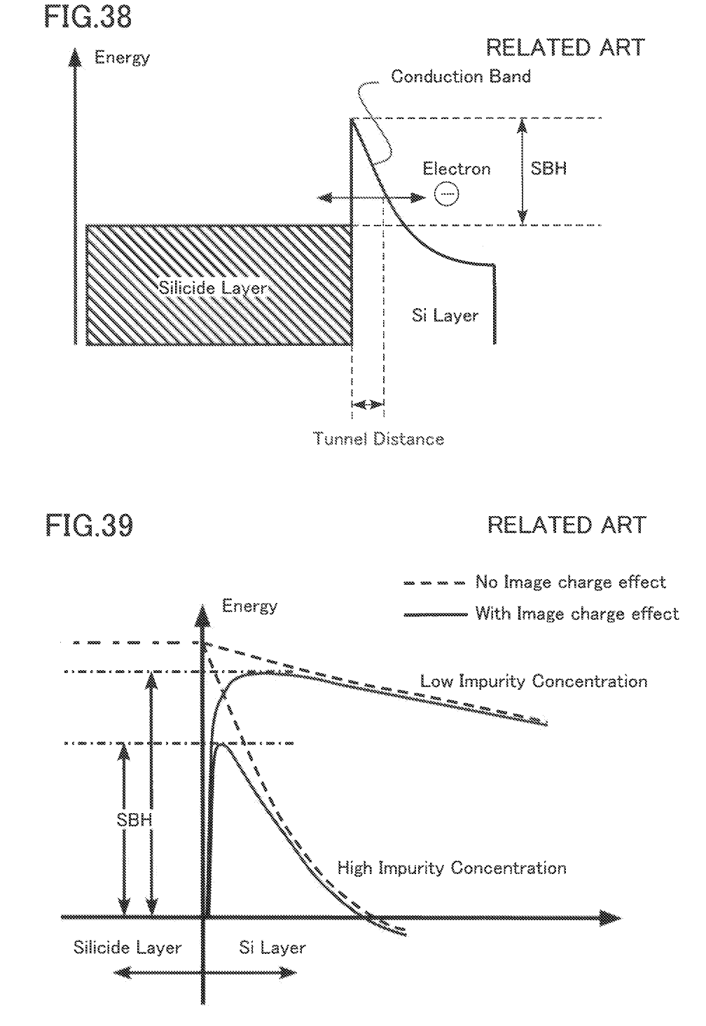

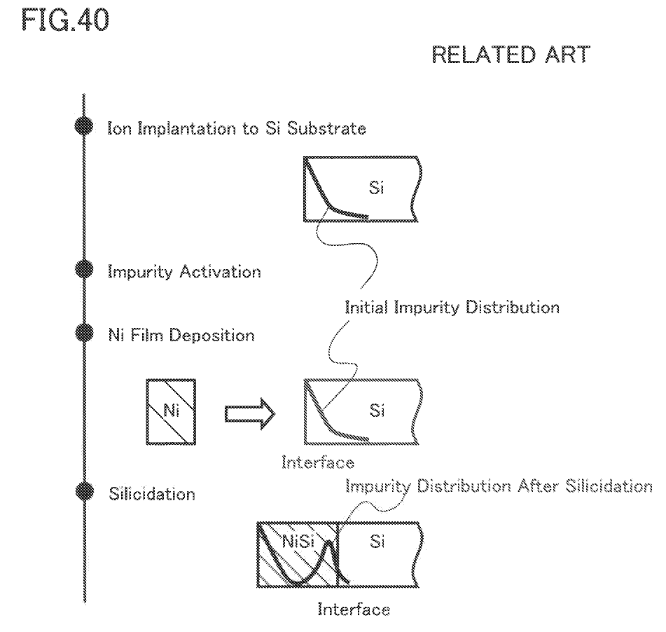

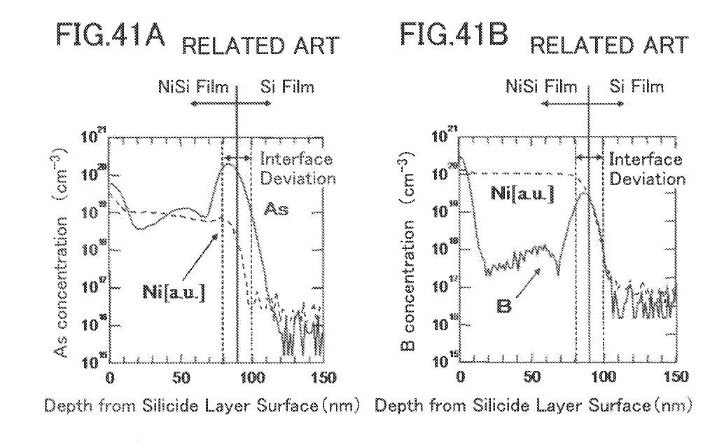

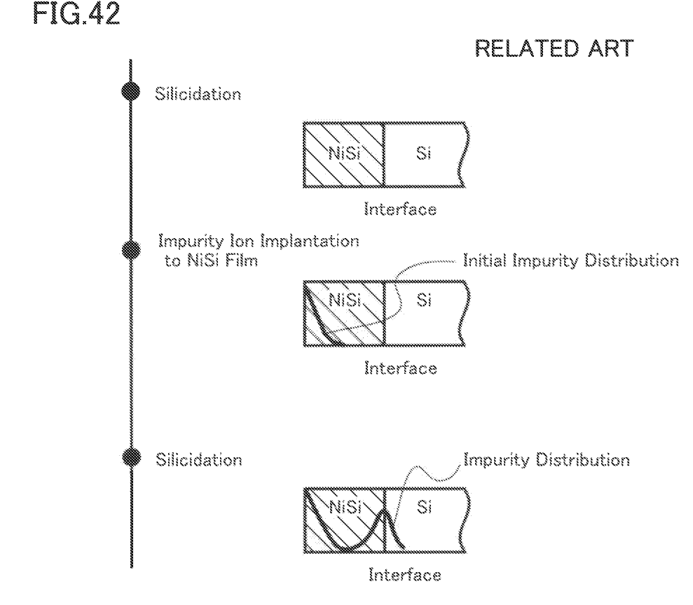

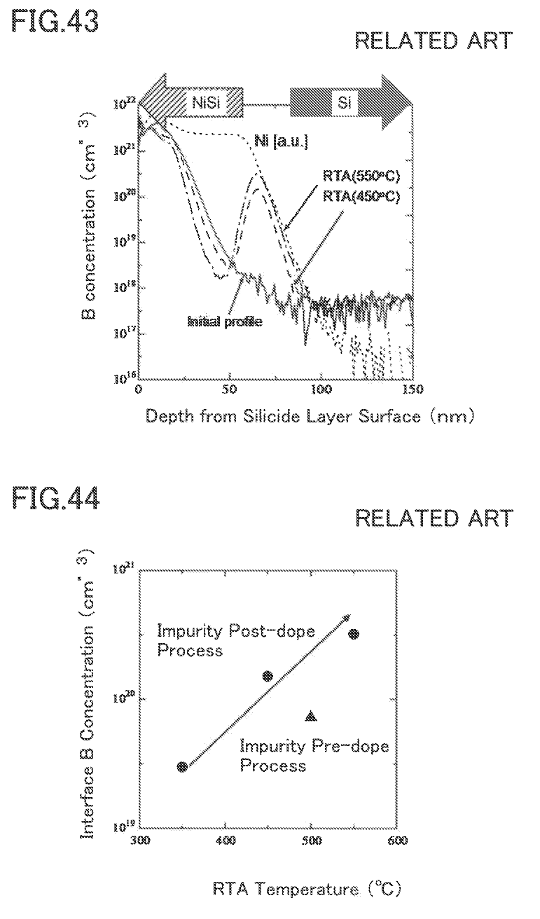

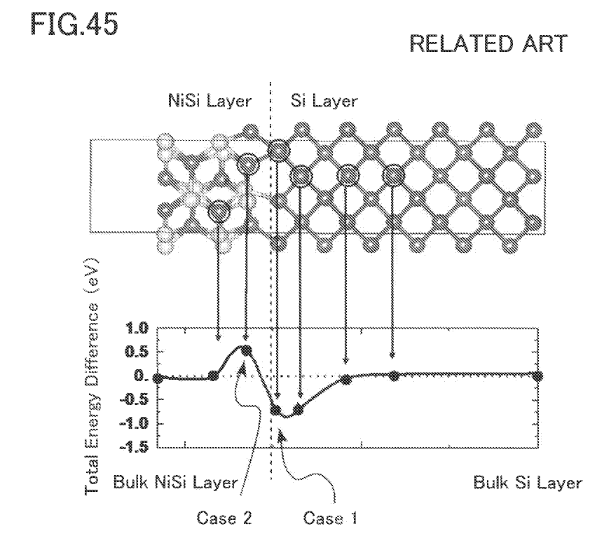

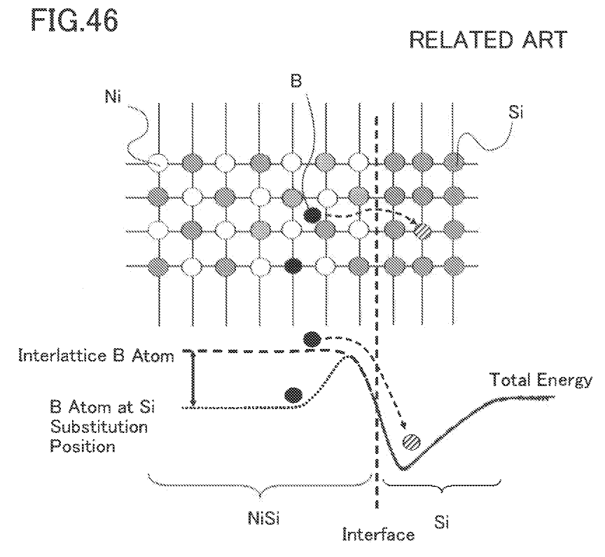

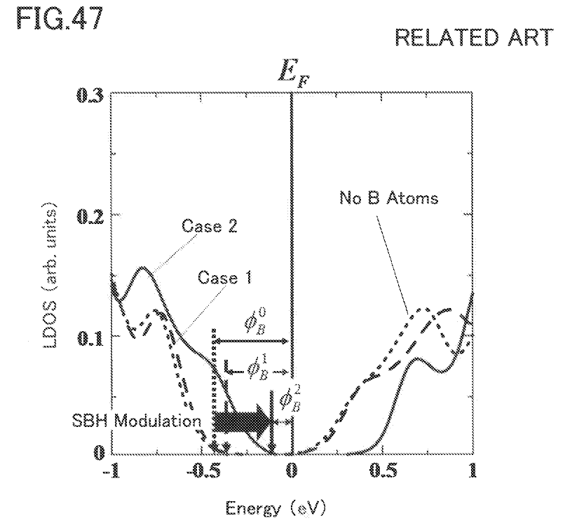

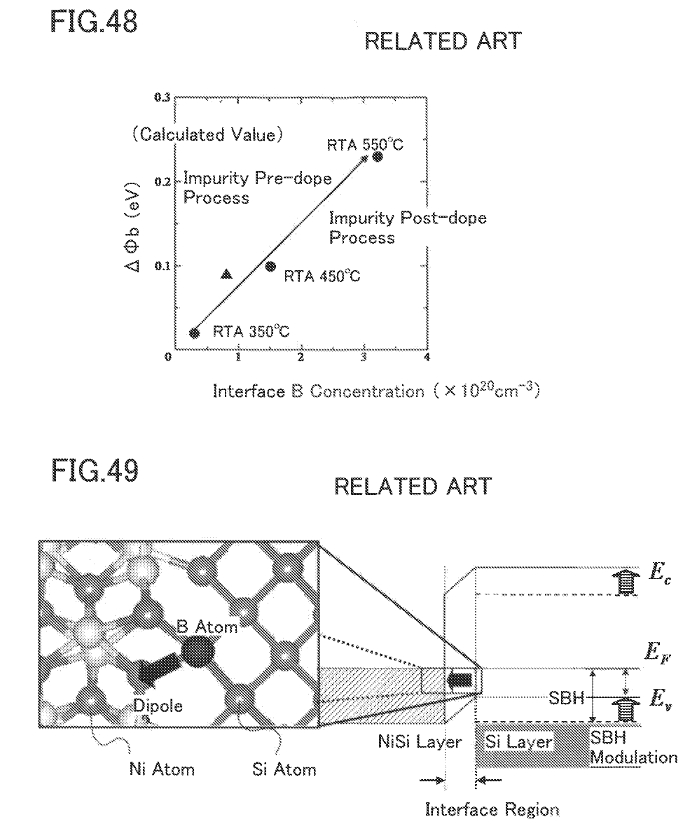

Next, as shown in FIG. 36, with the sidewall insulating film 216 of gate electrode 208 and a patterned resist film (not shown) being used as a mask, Mg is introduced by ion implantation into NiSi layer 240. Process conditions for this ion implantation are set so that a peak of the concentration distribution profile of Mg atoms immediately after completion of the ion implantation enters within NiSi layer 240. Setting the impurity ion implantation conditions in this way permits Mg atoms to exhibit effective segregation through thermal processing to be later performed. This enables the Mg interface layer to further increase in impurity concentration. Subsequently, with the sidewall insulating film 216 of the other gate electrode 208 and a patterned resist film (not shown) being used as a mask, Se is ion-implanted into NiSi layer 240. Process conditions for this ion implantation are set so that a peak of the concentration distribution profile of Se atoms thus implanted enters within NiSi layer 240. By setting the impurity doping conditions in this way, it is possible to effectively segregate Se atoms by thermal processing to be later performed, thereby enabling the Se interface layer to further increase in impurity concentration.

Then, second thermal processing is performed. More precisely, a 550° C., 30-sec RTA is performed. By this thermal processing, Mg atoms in NiSi layer 240 segregate to the substrate side of the interface between NiSi layer 210 and Si substrate 100 based on the above-stated impurity post-doping process principle, resulting in a Mg-containing interface layer 230 being formed as shown in FIG. 28. Similarly, by the second thermal processing, Se atoms in NiSi layer 210 segregate to the substrate side of the interface between NiSi layer 210 and Si substrate 100 based on the above-stated impurity post-doping process principle, resulting in a Se-containing interface layer 330 being formed as shown in FIG. 28.

According to the CMISFET device fabrication method also embodying the invention, it is possible to form the Mg-containing high-concentration interface layer in the pMISFET by effective segregation of Mg atoms to the substrate side of the NiSi/Si layer interface at which Mg atoms become energetically stable. For the nMISFET, it is possible to form the Se-containing high-concentration interface layer by effective segregation of Se atoms to the substrate side of the NiSi/Si layer interface at which Se atoms become energetically stable. This enables both the pMISFET and the nMISFET to decrease in interface resistance of source/drain electrodes, thereby making it possible to achieve a semiconductor device of the type having the CMIS transistor structure with enhanced performances.

It should be noted that in the fabrication method above, Ca or Ba impurity atoms may be used in place of Mg atoms while replacing Se to Te. In this case also, similar results are obtainable in terms of the formation of the heavily-doped interface layer with an increased impurity concentration. This can be said because these atoms are similar to Mg and Se in that the energetically stable impurity substitution position resides on the substrate side of the interface between the Si substrate and NiSi layer.

Also note that in the semiconductor device and its fabrication method of this embodiment, adding Pt to the NiSi layer makes it possible to suppress unwanted increase in junction leakage otherwise occurring due to abnormal diffusion of extra Ni atoms in NiSi layer to the transistor channel part, although the invention should not be construed to exclude the use of other possible Ni-containing metal silicide layers, such as a “pure” NiSi material which does not contain Pt or like materials.

Although the invention has been disclosed and illustrated with reference to particular embodiments, the principles involved are susceptible for use in numerous other embodiments, modifications and alterations which will be apparent to persons skilled in the art to which the invention pertains. The invention is, therefore, to be limited only as indicated by the scope of the appended claims, with possible equivalents involved therein.

What is claimed is:

1. A semiconductor device comprising:
a semiconductive substrate; and
a p-type metal insulator semiconductor field effect transistor (“p-MISFET”) on the substrate;
wherein
the p-MISFET including,
a channel region in the substrate,
a gate insulating film on the channel region,
a gate electrode on the gate insulating film,
a pair of source/drain electrodes at both sides of the channel region, each of the source/drain electrodes being formed of a nickel (Ni)-containing silicide layer, and
an interface layer at a substrate side of an interface between each of the source/drain electrodes and the substrate, the interface layer containing therein at least one of magnesium (Mg), calcium (Ca) and barium (Ba).

2. The device according to claim 1, wherein a total concentration of Mg, Ca and Ba in the interface layer is 1×10²¹ atoms/cm³ or greater.

3. The device according to claim 1, wherein the p-MISFET further includes:
a p-type impurity layer provided between the interface layer and the channel region and containing therein any one of boron (B), aluminum (Al) and indium (In).

4. The device according to claim 2, wherein the p-MISFET further includes:
a p-type impurity layer provided between the interface layer and the channel region and containing therein any one of B, Al and In.

5. A semiconductor device comprising:
a semiconductor substrate; and
an n-type metal insulator semiconductor field effect transistor (n-MISFET) on the substrate;
wherein
the n-MISFET including,
a channel region in the substrate,
a gate insulating film on the channel region,
a gate electrode on the gate insulating film,
a pair of source/drain electrodes at both sides of the channel region, each of the source/drain electrodes being formed of a nickel (Ni)-containing silicide layer, and
an interface layer at a substrate side of an interface between each of the source/drain electrodes and the substrate, the interface layer containing therein at least one of selenium (Se) and tellurium (Te).

6. The device according to claim 5, wherein a total concentration of Se and Te in the interface layer is 1×10²¹ atoms/cm³ or greater.

7. The device according to claim 5, wherein the n-MISFET further includes:
an n-type impurity layer provided between the interface layer and the channel region and containing any one of phosphorus (P), arsenic (As) and antimony (Sb).

8. The device according to claim 6, wherein the n-MISFET further includes:
an n-type impurity layer provided between the interface layer and the channel region and containing any one of P, As and Sb.

9. A method of fabricating a semiconductor device having on a semiconductor substrate a p-type metal insulator semiconductor field effect transistor (p-MISFET), the method comprising:
forming a gate insulating film on the substrate;
forming a gate electrode on the gate insulating film;
depositing on the substrate a nickel (Ni)-containing metal film;
performing first thermal processing for causing the metal film to react with the substrate to thereby form a metal silicide layer on both sides of the gate electrode;
ion implanting any one of magnesium (Mg), calcium (Ca) and barium (Ba) into the metal silicide layer; and
performing second thermal processing for segregating any one of the Mg, Ca and Ba to a substrate side of an interface between the substrate and the metal silicide layer.

10. The method according to claim 9, further comprising:
prior to the ion implanting of Mg, Ca or Ba into the metal silicide layer, ion implanting any one of boron (B), aluminum (Al) and indium (In) into the metal silicide layer.

11. The method according to claim 9, further comprising:
before the ion implanting of Mg, Ca or Ba into the metal silicide layer, ion implanting any one of carbon (C) and fluorine (F) into the metal silicide layer.

12. The method according to claim 10, further comprising:
before the ion implanting of Mg, Ca or Ba into the metal silicide layer, ion implanting any one of C and F into the metal silicide layer.

13. A method of fabricating a semiconductor device having on a semiconductor substrate an n-type metal insulator semiconductor field effect transistor (n-MISFET), comprising:
forming a gate insulating film on the substrate;
forming a gate electrode on the gate insulating film;
depositing on the substrate a nickel (Ni)-containing metal film;
performing first thermal processing for causing the metal film to react with the substrate to thereby form a metal silicide layer on both sides of the gate electrode;
ion implanting any one of selenium (Se) and tellurium (Te) into the metal silicide layer; and
performing second thermal processing for segregating any one of the Se and Te to a substrate side of an interface between the substrate and the metal silicide layer.

14. The method according to claim 13, further comprising:
prior to the ion implanting of Se or Te into the metal silicide layer, ion implanting any one of phosphorus (P), arsenic (As) and antimony (Sb) into the metal silicide layer.

15. The method according to claim 13, further comprising:
prior to the ion implanting of Se or Te into the metal silicide layer, ion implanting any one of carbon (C) and fluorine (F) into the metal silicide layer.

16. The method according to claim 14, further comprising:
before the ion implanting of Se or Te into the metal silicide layer, ion implanting any one of C and F into the metal silicide layer.
